(19) United States
(12) Patent Application Publication
(10) Pub. No.: US 2024/0417619 A1
(43) Pub. Date: Dec. 19, 2024

(54) LUMINESCENT MATERIAL AND MINI-LED DEVICE PREPARED USING LUMINESCENT MATERIAL

(71) Applicant: XIAMEN UNIVERSITY, Fujian (CN)

(72) Inventors: Rongjun XIE, Fujian (CN); Tongtong XUAN, Fujian (CN); Tianliang ZHOU, Fujian (CN); Wenhao BAI, Fujian (CN)

(21) Appl. No.: 18/704,949

(22) PCT Filed: Oct. 26, 2021
(86) PCT No.: PCT/CN2021/126293

§ 371 Date: Apr. 26, 2024

(51) Int. Cl. C09K 11/66; C09K 11/55; C09K 11/61

(52) U.S. Cl. CPC C09K 11/66; C09K 11/55; C09K 11/61; C09K 2211/10

(57) ABSTRACT

The present invention relates to a luminescent material and a Mini-LED device prepared by the luminescent material; the luminescent material is formed by compounding a porous material and a luminescent substance, and has a chemical formula of: N@AX·aPbX₂·bMX₂, where N denotes the porous material, @ denotes compounding, and AX·aPbX₂·bMX₂ denotes the luminescent substance, where A is at least one of Cs and Rb, X is at least one of Cl, Br, and I; M is at least one of Mg, Ca, Sr, Ba, Zn, and Cu. and 0.7<a≤1, 0<b≤0.3, and 0.7<a+b<1. The luminescent material has an excellent luminescence property, higher moisture stability, oxygen stability, light stability, and heat stability. High-performance Mini-LED devices can be prepared using the luminescent material prepared in the present application in combination with a blue Mini-LED chip.

### TECHNICAL FIELD

The present invention relates to the technology of functional materials preparation, and in particular to a luminescent material and a Mini-LED device prepared using the luminescent material.

### BACKGROUND

Mini LED, also called “sub-millimeter light emitting diode”, is a kind of technology between conventional LED and Micro LED. In process level, compared with Micro LED. Mini LED has a higher yield and is easier to achieve mass production; moreover, it can be greatly developed in the liquid crystal display (LCD) backlight market; its product is more economic. Moreover, Mini LED can be matched with a flexible substrate to achieve a high curved backlight form; with local dimming design, Mini LED has better color rendering properties and can bring more refined high dynamic range (HDR) partitions for LCD panels, and its thickness is also approaching that of organic light-emitting diode (OLED), capable of saving electricity being up to 80%. Mini LED is particularly appropriate for the products demanding for power saving, thinness and high HDR, such as mobile phones, TVs, vehicle panels and laptops for electronic sports.

Colorization is the key to commercialization for Mini LED technology. Methods for achieving colorization include RGB LEDs, UV/blue LED+luminescent material method, synthesis method of optical lens, and the like. In the RGB colorization display method, each pixel contains three RGB LEDs. Generally, electrodes P and N of the trichromatic LED are connected to a circuit board in a bonding or inverted way; afterwards, each LED is subjected to pulse width modulation (PWM) current driving with a dedicated full-color LED driver chip. The PWM current driving way can achieve digital dimming by setting a current effective period and duty cycle. However, in fact, there exists an error between the actual output current of the driver chip and theoretical current; each LED of an individual pixel has a certain half-wave spectral width (the narrower the full width at half maximum is, the better the color rendering property of LED is) and luminous attenuation phenomenon such that the deviation of LED pixel full-color display is thus generated. The synthesis method of optical lens refers that RGB LED is synthesized to full-color display with an optical prism. The specific method is as follows: trichromatic (red, green, and blue, i.e., RGB) LED arrays are respectively encapsulated onto three encapsulating boards, and connected with a control board and a trichromatic prism. The device obtained by the synthesis method of optical lens is slightly thick in size.

The UV/blue LED+luminescent material method is the simplest method for the Mini LED technology to achieve colorization. Luminescent materials can be generally divided into fluorescent powder and quantum dot. As to fluorescent powder, its particle size is large, being about 1-10 μm; as the LED pixel size decreases continuously, the coating nonuniformity of fluorescent powder will affect the display quality. Quantum dot has electroluminescent and photoluminescent effects, and can emit fluorescence after being excited. Its emitting color depends upon materials and size. Therefore, the particle size of quantum dot can be regulated to change its different light-emitting wavelengths. The smaller the particle size of quantum dot is, the bluer the emitting color is; and the larger the quantum dot is, the redder the quantum dot is. Quantum dot contains a variety of chemical components and its emitting color can cover the whole visible region from blue to red rays. Moreover, quantum dot features in high-capacity light absorption-luminous efficiency, very narrow FWHM, wide absorption spectrum, and the like and thus, has very high color purity and saturability.

However, the quantum dot technology has been not yet mature enough; there are some disadvantages such as poor material stability, high requirements for heat dissipation, short service life, and it needs to be sealed and is prone to decomposition under the action of light, heat, water or oxygen, leading to sharp fluorescence quenching. This greatly limits the application range of the technology and seriously hinders its commercial application process in the field of Mini-LED display.

Currently, there are following three categories of methods for enhancing the stability of quantum dot:

(1) Component regulating engineering, i.e., stability can be enhanced by increasing the formation energy of quantum dot by component regulation, but this method merely achieves limited effect in enhancing the stability of quantum dot.

(2) Surface engineering, i.e., the stability of quantum dot in the air is enhanced by modifying a waterproof surface ligand. This method can enhance the stability of quantum dot to some extent, but the surface modification efficiency is low and the thermal quenching property of the obtained quantum dot has been not yet up to the encapsulating requirements.

For example, open literature 1 (Qionghua Mo, Chen, Wensi Cai, Shuangyi Zhao, Dongdong Yan, Zhigang Zang, Room Temperature Synthesis of Stable Zirconia-Coated CsPbBr₃ Nanocrystals for White Light-Emitting Diodes and Visible Light Communication, Early View, Laser & Photonics Reviews, https://doi.org/10.1002/lpor.202100278) discloses: type-I heterojunctions are formed using zirconia-coated CsPbBr₃ nanocrystals with a broad bandgap, thus significantly improving the quantum yield, heat stability and moisture stability of nanocrystals. In addition, WLEDs based on such kind of coated nanocrystal can be used as visible light communication with a −3 dB bandwidth of 2.7 MHz, showing typical low-pass frequency response.

(3) Encapsulating engineering, i.e., quantum dots are embedded into a porous material to enhance the stability of quantum dots.

For example, open literature 2 (Weiqiang Yang, Fei Gao, Yue Qiu, Weizhen Liu, Haiyang Xu, Lili Yang, Yichun Liu, CsPbBr₃-Quantum-Dots/Polystyrene@Silica Hybrid Microsphere Structures With Significantly Improved Stability for White LEDs, Advanced Optical Materials, 7, 2019: 1900546) discloses: fluorescent microspheres (CsPbBr₃-PQDs/MPMs@SiO₂) having a high quantum yield of 84% are generated by a strategy of encapsulating mesoporous polymer microspheres (MPMs) together with silica. The method also improves the stability of CsPbBr₃ in water. Meanwhile, the silica shell coated on the structure surface improves the heat stability of CsPbBr₃; about 60% of initial fluorescence intensity is still maintained after being heated at 80° C. for 40 min. However, the mesoporous microspheres adopted are polymers; therefore, the aging resistance of the material is poor.

For another example, Chinese patent CN104774611B discloses hydrothermal synthesis by means of a molecular sieve; carbon dots of two light-emitting behaviors dependent/independent of excitation wavelength can be obtained by controlling synthesis and post-processing conditions. Molecular sieve-compounded carbon quantum dots prepared by calcining molecular sieve crystals give out light within 450 580 nm; moreover, solid powder samples can be stored for a long time and liquid samples can be used upon being dissolved. In this method, a hydrothermal reactor is adopted for preparation; reaction time is long and reaction conditions are demanding; moreover, the composite quantum dot@molecular sieve material has lower luminescent intensity, obvious fluorescence quenching, and very poor thermal quenching property, extremely low luminescent intensity when applied to Mini LED encapsulation and thus, is not applicable.

Furthermore, Chinese patent application CN106920855A provides a composite cadmium selenide quantum dot-nanoporous carbon material more stable than polymers, and a preparation method thereof. The composite cadmium selenide quantum dot-nanoporous carbon material is compounded by cadmium selenide quantum dots and nanoporous carbon; the cadmium selenide quantum dots are in situ grown on the surface of the nanoporous carbon; and the nanoporous carbon is obtained by calcining zeolite-imidazate coordination polymers under the protection of inert gas. Even though the invention relates to a photocatalytic material, its synthetic method can be applied to obtain a composite luminescent porous carbon-quantum dot material. However, carbon material is black, the obtained composite material is thus not suitable as a luminescent material.

US patent U.S. Pat. No. 9,287,120B2 discloses a composite zeolite-quantum dot luminescent material. In the invention, quantum dots are adsorbed by means of the adsorption capacity of zeolite pores, and the quantum dots entering the pores can still maintain the original luminescent property. Nevertheless, the luminescent material obtained via the technology has very poor stability; quantum dots are very prone to desorbing from the pores and thus, are decomposed under environment variables such water and oxygen.

JP patent JP6507284B2 discloses a technology, i.e., desorption of quantum dots is avoided by adsorbing quantum dots with a porous material and blocking pores with an organic matter. The technology can effectively avoid the problem existing in the US patent U.S. Pat. No. 9,287,120B2, thus further promoting the stability of the composite porous material quantum dot. However, the technical solution has complex process routes and blocks pores with an organic matter. Because the aging resistance and photo-thermal resistance of organic matter are poor, the obtained material is very prone to be disabled, resulting in failure in work after being encapsulated.

As an improved technical solution, Chinese patent CN106928997A provides a luminescent particle and a luminescent device comprising the same. The luminescent particle includes a molecular sieve and a quantum dot material; the quantum dot material is filled into internal pores of the molecular sieve as a framework, and the surface of the molecular sieve is further provided with a coating film. The molecular sieve has stability at high temperature, and the coating film can enhance the water resistance of the quantum dot; therefore, the quantum dot material is filled into internal pores of the molecular sieve as a framework such that quantum dots maintain a stable luminescence property under the protection of silica and other coating films, and accordingly the luminescent particle has a stable luminescence property. Silica and other inorganic coating films are cladded on the outside of the molecular sieve, which needs to be conducted under aqueous phase conditions. Therefore, the method is not suitable for quantum dot materials insensitive to water. Even though a reactive mode of non-aqueous system is adopted, desorption of the quantum dot material will occur in the cladding process. Therefore, the composite porous quantum dot material obtained by the method has lower luminescent intensity, and the encapsulated device has lower efficiency.

Chinese patent CN107118769A discloses another technical solution of composite porous material quantum dots, i.e., by means of an ion exchange method, a molecular sieve is first mixed with one of the quantum dot components to obtain an ion exchanged molecular sieve, and other quantum dot components are then added to obtain the composite luminescent material containing the quantum dot material within pores finally. Water resistance of the luminescent material obtained by the invention is certainly very poor. Given that pores are blocked via cladding and other ways, silica and other inorganic coating films are cladded on the outside of the molecular sieve, which needs to be conducted under aqueous phase conditions. Therefore, the method is not suitable for quantum dot materials insensitive to water. Even though a reactive mode of non-aqueous system is adopted, desorption of the quantum dot material will occur in the cladding process. Therefore, the composite porous quantum dot material obtained by the method has lower luminescent intensity, and the encapsulated device has lower efficiency.

For a further example, Chinese patent CN110734758B discloses a method for preparing a fluorescent semiconductor nanocrystal material, including the following steps: 1) uniformly mixing a nanocrystal precursor with a micro/mesoporous material; and 2) calcining under a condition higher than or equal to a collapse temperature of the micro/mesoporous material to make pores of the micro/mesoporous material collapse, to produce the fluorescent semiconductor nanocrystal material. Since pores of the micro/mesoporous material collapse at high temperature, the semiconductor nanocrystal is encapsulated into pores of the micro/mesoporous material. However, the method has the following problems: firstly, pores of the micro/mesoporous material collapse to block the water vapor channel of the pores, isolating the fluorescent semiconductor nanocrystal material from the external environment, but there still exist oxygen and other substances in the internal pores, these substances will gradually be subjected to chemical reactions with the fluorescent semiconductor nanocrystal material, lowering the luminescent intensity. Secondly, collapse of pores of the micro/mesoporous material will make the fluorescent semiconductor nanocrystal material suffering extruding deformation such that the crystal is broken and cracked, thus resulting in reduced luminescent intensity. Finally, it is impossible for the nanocrystal precursors to get into the internal pores of the micro/mesoporous material when mixed therewith; a considerable amount of nanocrystal precursors will be certainly adsorbed on the surface of the micro/mesoporous material, if these absorbed nanocrystal precursors are not removed in an appropriate way, it will inevitably lead to the change of the overall luminescence property of the material during use.

Of course, there are composite fluorescent particles prepared by quantum dots, mesoporous materials, water and oxygen-blocking materials. Water and oxygen-blocking organics are filled between quantum dots and the mesoporous material, thus improving the water and oxygen resistances of the composite fluorescent quantum dot particles. However, the method has a complex preparation process, and the applied water and oxygen-blocking organics have poor stability. The obtained composite fluorescent particle has a poor aging resistance; for example, Chinese patent CN105733556B.

Therefore, there is, obviously, a lack of an open technical solution on the preparation of a composite porous material quantum dot with simple synthetic process, strong water and light resistances, and excellent thermal quenching property at present.

### SUMMARY

The objective of the present invention is to overcome the shortcomings in the existing preparation technology of quantum dots, and provide a luminescent material having a chemical formula represented as: N@AX·aPbX₂·bMX₂; where N denotes a porous material; @ denotes compounding; AX·aPbX₂·bMX₂ denotes a luminescent substance, where A may be at least one of Cs and Rb; X is at least one of Cl, Br, and I, and M may be at least one of Mg, Ca, Sr, Ba, Zn, and Cu; 0.7<a≤1, 0<b≤0.3, and 0.7<a+b<1.

The material is not a perovskite structure in the traditional sense structurally, particularly in AX·aPbX₂·bMX₂, but chemical bonding is formed between AX·aPbX₂·bMX₂ and N. That is, a dangling bond on a surface of the AX·aPbX₂·bMX₂ contacts with a solvent to form a passivation layer subjected to chemical bonding with a dangling bond on the inside wall of a pore of the N, to form a stable chemical bond; and finally, the composite porous material luminescent substance having a chemical formula represented as: N@AX·aPbX₂·bMX₂ is obtained; where N denotes a porous material; 4 denotes compounding; AX·aPbX₂·bMX₂ denotes a luminescent substance, where A may be at least one of Cs and Rb; X is at least one of Cl, Br, and I; and M may be at least one of Mg, Ca, Sr, Ba, Zn, and Cu; 0.7<a≤1, 0<b≤0.3, and 0.7<a+b<1. Based on the luminescent material N@AX·aPbX₂·bMX₂ obtained in the present invention, the way to fixing AX·aPbX₂·bMX₂, as a core luminescent substance, onto the porous material is neither simple physical absorption, nor the way of blocking pores of the porous material (including but not limited to: pore blocking via pore collapse to isolate water and oxygen, isolation of water and oxygen via coating a film on the surface of a porous material, as well as isolation of water and oxygen via filling pores with organics), let alone the way of cladding a luminescent material and then assembling with a porous material, thus achieving compounding.

The technical means adopted in the present invention is to achieve direct chemical bonding between AX·aPbX₂·bMX₂ passivated by a solvent and the porous material N; a proper heat treatment temperature is selected under high-temperature treatment conditions such that chemical bonding is performed between the dangling bond on the surface of the passivated AX·aPbX₂·bMX₂ and the dangling bond in the pores of the porous material; the porous material and pores of the porous material will not and need not collapse, and finally, the passivated AX·aPbX₂·bMX₂ and N form an integrity, thereby maintaining its stable luminescence property. For the control of the chemical components, i.e., the composite luminescent material having a chemical formula represented as: N@AX·aPbX₂·bMX₂, N denotes a porous material; @ denotes compounding: AX·aPbX₂·bMX₂ denotes a luminescent substance, where A may be at least one of Cs and Rb; X is at least one of Cl, Br, and I; and M may be at least one of Mg, Ca, Sr, Ba, Zn, and Cu; 0.7<a≤1, 0<b≤0.3, and 0.7<a+b<1. A non-stoichiometric substance is formed by changing the component of X; emission spectrum of the composite luminescent substance can be regulated certainly, and most importantly, the stability of the composite luminescent substance can be regulated by adjusting the ratio of a to b. This is because changing the ratio of a to b means that the number and type of the dangling bonds on the surface of the passivated AX·aPbX₂·bMX₂ will change, making the intensity and variety of the chemical bonding with the dangling bonds on the inside wall of pores of the N changed accordingly, which will further affect the stability of the composite luminescent material (including but not limited to the thermal quenching property, water resistance, light stability, and the like). Stability is just the major concern in this field. Meanwhile, the composite luminescent material N@AX·aPbX₂·bMX₂ is subjected to centrifugal washing with water, which can effectively remove the luminescent substance or raw material that has been not reacted completely in the porous material, or the luminescent substance and impurities adsorbed on the surface of the porous material, thus further improving the chemical stability and operational performance of the composite luminescent material.

### Beneficial Effects

In the present invention, the porous material is adopted in the luminescent material as a framework material to adsorb a nanocrystal precursor. When the nanocrystal precursor is calcined at high temperature, the porous material per se and its pore structure will not collapse, and a porous structure is still maintained; therefore, after the nanocrystal within the product contacts with water and the like in the porous material, a stable passivation layer is formed on the surface and generates a composite with the porous material finally. In such a way, the present invention not only has an excellent luminescence property, but also has ultra-strong stability, particularly stability in water.

Furthermore, the present invention improves the performance of the material via component control, including: (1) a non-stoichiometric technical solution is adopted to achieve the regulation of the perovskite bandgap and obtain three-color (red, green and blue) luminescent material; (2) the technical solution, i.e., conducting chemical bonding between the dangling bond on the surface of the passivated AX·aPbX₂·bMX₂ and the dangling bond in the pores of the porous material, is adopted to enhance the binding energy of the perovskite quantum dots and improve its chemical structure and thermodynamic stability.

Furthermore, on the basis of component control, the present invention forms a porous microstructure on the surface of the luminescent material in combination with the features of the porous material such that a minute amount of water enter pores and then is reacted with perovskite quantum dots to form a passivation layer, thus further effectively hindering the entry of water and enhancing the water resistance. The dangling bond generated on the surface of the passivated AX·aPbX₂·bMX₂ is subjected to chemical bonding with the dangling bond in the pores of the porous material to form a stable structure, thereby significantly improving the light and heat stability of the luminescent material.

In conclusion, the method for preparing a luminescent material provided in the present invention has the advantages of simple operation, low costs, large-scale preparation, and is thus suitable for industrial production. Moreover, the luminescent material prepared in the present application has an excellent luminescence property, higher water, oxygen, light and heat stability. High-performance Mini-LED devices can be prepared using the luminescent material prepared in the present application in combination with a blue Mini-LED chip.

### BRIEF DESCRIPTION OF DRAWINGS

To describe the technical solutions of the present invention more clearly, the accompanying drawings will be briefly described below. Apparently, the accompanying drawings described below merely relate to some examples of the present invention, but are not construed as limiting the present invention.

FIG. 1 shows an emission spectrum of a material under the excitation of a 365 nm blue ray provided in Example 1 of the present invention; and

FIG. 2 shows a variation over time of the quantum efficiency of a luminescent material under the excitation of a 365 nm blue ray provided in Example 7 of the present invention.

### DESCRIPTION OF EMBODIMENTS

A portion of terms used in the present invention are defined below, and other terms not mentioned herein are subjected to the definitions and meanings commonly known in the art:

The luminescent material provided in the present invention has the following chemical formula: N@AX·aPbX₂·bMX₂, where @ denotes compounding; N denotes the porous material and may be at least one of mesoporous silica (surface pore diameter: 2-10 nm), a KIT-6 molecular sieve, an MCM-41 molecular sieve, an SBA molecular sieve, an MCM-22 molecular sieve, a titanium silicon molecular sieve TS-1, an SAPO-34 molecular sieve, an SAPO-11 molecular sieve, a ZSM-5 molecular sieve, a Y-type molecular sieve, a ZSM-35 molecular sieve, a β molecular sieve, a ZSM-23 molecular sieve, a 3A molecular sieve, 4A molecular sieve, A 5A molecular sieve, and a 13X molecular sieve. In some examples provided in the present invention, the N is preferably an SBA molecular sieve; in some examples provided in the present invention, the N is preferably Y-type molecular sieve; and in some other examples provided in the present invention, the N is preferably a 5A molecular sieve.

AX·aPbX₂·bMX₂ denotes the luminescent substance, where A may be at least one of Cs and Rb. In some examples provided in the present invention, the A is preferably Cs.

AX·aPbX₂·bMX₂ denotes the luminescent substance, where X is at least one of Cl, Br, and I. In some examples provided in the present invention, the X is preferably Cl.

AX·aPbX₂·bMX₂ denotes the luminescent substance, where M is at least one of Mg, Ca, Sr, Ba, Zn, and Cu. In some examples provided in the present invention, the X is preferably Sr.

AX·aPbX₂·bMX₂ denotes the luminescent substance, furthermore, preferably, in some examples provided in the present invention, the AX is preferably CsCl.

AX·aPbX₂·bMX₂ denotes the luminescent substance, furthermore, preferably, in some examples provided in the present invention, the PbX₂ is preferably PbCl₂.

AX·aPbX₂·bMX₂ denotes the luminescent substance, furthermore, preferably, in some examples provided in the present invention, the MX₂ is preferably SrCl₂.

AX·aPbX₂·bMX₂ denotes the luminescent substance, where 0.7<a≤1, 0<b≤0.3, and 0.7<a+b<1. In some examples provided in the present invention, the a is preferably 0.75, and the b is preferably 0.05; in some examples provided in the present invention, the a is preferably 0.8 and the b is preferably 0.15; and in some other examples provided in the present invention, the a is preferably 0.95, and the b is preferably 0.04.

In some examples provided in the present invention, the preparation process of the luminescent material contains the following 6 steps: in the step (1), the A-containing compound, the Pb-containing compound and the M-containing compound are mixed in a proportion of AX·aPbX₂·bMX₂ as a nominal composition, and completely dissolved into the solvent S at 50-90° C., to obtain a solution Q having a certain concentration and a solute having a nominal composition of AX·aPbX₂·bMX₂.

Preferably, in the step (1), in some examples provided in the present invention, the beating temperature is preferably 80° C.

Preferably, the solvent S may be water or a haloid acid, particularly, in the step (1), when the M-containing compound is selected from a nitrate containing Mg, Ca, Sr, Ba, Zn, and Cu, the solvent S must be a haloid acid. In the examples of the present invention, M is derived from halides of M; therefore, in some examples provided in the present invention, S is preferably water.

Preferably, in the step (1), the solution Q with a solute having a nominal composition of AX·aPbX₂·bMX₂ has amass concentration of 5 g/L-100 g/L, where, 0.7<a≤1; 0<b≤0.3; and 0.7<a+b<1. Preferably, in some examples provided in the present invention, the solution Q with a solute having a nominal composition of AX·aPbX₂·bMX₂ has a mass concentration of 50 g/L, where the a=0.8 and the b=0.18.

In some examples provided in the present invention, the preparation process of the luminescent material contains the following 6 steps: in the step (2), certain mass of N is added to the solution Q obtained in the step (1) and stirred at 50-90° C. for 2 h to obtain a solution R; in the step (2), the mass ratio of N to Q is within 0.1:1-0.5:1.

Preferably, in some examples provided in the present invention, in the step (2), the heating temperature is preferably 80° C., and the mass ratio of N to Q is 0.2:1.

In some examples provided in the present invention, the preparation process of the luminescent material contains the following 6 steps: in the step (3), the solution R obtained in the step (2) is evaporated at 80° C. until the solvent S is completely volatilized, to obtain a powder G.

In some examples provided in the present invention, in the step (3), the preparation process of the luminescent material contains the following 6 steps, in the step (4), the powder G is calcined for a period of time at a certain high temperature, to obtain a powder T.

Preferably, in the step (4), the calcination temperature is 450-900° C., and the calcination time is 0.5-6 h. In some examples provided in the present invention, the calcination temperature is preferably 500° C. and the calcination time is preferably 1 h.

In some examples provided in the present invention, the preparation process of the luminescent material contains the following 6 steps, in the (5), the powder T is added to a certain volume of water, and stirred at room temperature for 0.5-2 h, and then centrifuged to obtain a precipitate H.

Preferably, in the step (5), a mass ratio of the certain volume of water to the powder T is 1:1-1:5; the centrifugation rate is 500-3,000 rmp. In some examples provided in the present invention, the mass ratio of the certain volume of water to the powder T is 1:2; and the centrifugation rate is preferably 2,500 rmp.

In some examples provided in the present invention, the preparation process of the luminescent material contains the following 6 steps, in the (6), the precipitate H is placed into a 50-90° C. oven and heated for 6-24 h, to obtain the luminescent material of claim 1.

Preferably, in the step (6), the precipitate H is placed into a 50-90° C. oven and heated for 6-24 h. In some examples provided in the present invention, the drying temperature is preferably 80° C. and the drying time is preferably 12 h.

The present invention further provides an LED device, preferably a Mini-LED device including an LED chip with a size of (0.05 mm-0.2 mm)×(0.05 mm-0.2 mm) and a luminescent layer; the luminescent layer is a silica gel layer solidified with the luminescent material or an epoxy resin layer solidified with the luminescent material; the luminescent material accounts for 5-75% of a total mass of the luminescent layer by mass.

Preferably, in some examples provided in the present invention, the major peak of the emission wavelength of the LED chip is located at 460 nm; the luminescent material is preferably an SBA molecular sieve @ CsCl·0.8PbCl₂·0.18SrCl₂; the solidifying material of the luminescent layer is an epoxy resin; the luminescent material accounts for 50% of the luminescent layer (i.e., the epoxy resin layer containing the luminescent material) by mass.

Preferred embodiments of the present invention will be described below in more detail. Even though the preferred embodiments of the present invention are described below, it should be understood that the present invention may be achieved in various forms, but not limited by the embodiments set forth here. Specific technologies or conditions not specified in the examples shall be subjected to the technologies or conditions described in the literatures in the art or product manuals. Reagents or instrument used but not marked with a manufacturer shall be conventional products available commercially. In the following examples. “%” refers to a weight percentage, unless otherwise stated explicitly.

To further describe the present invention, a visible near-infrared luminescent material and a preparation method thereof provided in the present invention will be described in detail with reference to the examples below. Reagents used in the following comparative examples and examples are all commercially available.

### Comparative Example 1

A method for preparing a luminescent material provided in this comparative example includes the following specific steps:
(1) CsCl and PbCl₂ were heated at 80° C. in a proportion of CsCl·0.8PbCl₂ as its nominal composition and completely dissolved into a solvent water, to obtain a solution Q1 with a mass concentration of 50 g/L and containing a solute having a nominal composition of CsCl·0.8PbCl₂;
(2) SBA molecular sieve in certain mass was added to the solution Q1 obtained in the step (0) and stirred at 80° C. for 2 h to obtain a solution R1, where the mass ratio of the SBA molecular sieve to the solution Q1 was 0.2:1;
(3) the solution R1 obtained in the step (2) was evaporated at 80° C. until the solvent water was volatilized completely to obtain a powder G1;
(4) the powder G1 was calcined at 500° C. for 1 h to obtain a powder T1;
(5) the powder T1 was added to a certain volume of water, stirred at room temperature for 1 h, and then centrifuged at 2,500 rmp to obtain a precipitate H1, where the mass ratio of powder T1 to water is 1:2; and
(6) the precipitate H, 1 was placed into an 80° C. oven and dried for 12 h, to obtain a material.

The material obtained in Comparative Example 1 was measured by a fluorescence spectrophotometer; under the excitation of a 365 nm blue ray, the material has low luminescent intensity; the material obtained in Comparative Example 1 was heated up to 125° C. and its luminescent intensity was then measured and found to have only 18% of the measured value at room temperature; 1 g of the material obtained in Comparative Example 1 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be lower and could be hardly measured. Obviously, the material obtained in Comparative Example 1 had very poor stability. After the material obtained in Comparative Example 1 was radiated by a blue ray having a power density of 150 mW/cm² and a wavelength of 365 inn for 24 h, its luminescent intensity declined in a proportion of greater than 75% of its initial value. Test data of Comparative Example 1 is shown in Table 1.

### Comparative Example 2

A method for preparing a luminescent material provided in this comparative example includes the following specific steps:
(1) CsCl and PbCl₂ were heated at 80° C. in a proportion of CsCl·0.8PbCl₂ as the nominal composition and completely dissolved into a solvent water, to obtain a solution Q2 with a mass concentration of 50 g/L and containing a solute having a nominal composition of CsCl·0.8PbCl₂.
(2) SBA molecular sieve in certain mass was added to the solution Q2 obtained in the step (1) and stirred at 80° C. for 2 h to obtain a solution R2, where the mass ratio of the SBA molecular sieve to the solution Q2 was 0.2:1;
(3) SrCl₂ in certain mass was added to the solution R2 according to a proportion of obtaining a solute having a nominal composition of CsCl·0.8PbCl₂·0.18SrCl₂ available, and stirred at 80° C. for 2 h to obtain a solution R2-2;
(4) the solution R2-2 obtained in the step (3) was evaporated at 80° C. until the solvent water was volatilized completely to obtain a powder G2;
(5) the powder G2 was calcined at 500° C. for 1 h to obtain a powder T2;
(6) the powder T2 was added to a certain volume of water, stirred at room temperature for 1 h, and then centrifuged at 2.500 rmp to obtain a precipitate H2, where the mass ratio of powder T2 to water is 1:2; and
(7) the precipitate H2 was placed into an 80° C. oven and dried for 12 h, to obtain a material.

The material obtained in Comparative Example 2 was measured by a fluorescence spectrophotometer; under the excitation of a 365 nm blue ray, the material failed to give out light; the material obtained in Comparative Example 2 was heated up to 125° C. and its luminescent intensity was then measured and found to not emit light; 1 g of the material obtained in Comparative Example 2 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 2 was radiated by a blue ray having a power density of 150 mW/cm² and a wavelength of 365 nm for 24 h. it was found to not give out light. Test data of Comparative Example 2 is shown in Table 1.

### Comparative Example 3

A method for preparing a luminescent material provided in this comparative example includes the following specific steps:
(1) CsCl and PbCl₂ were heated at 80° C. in a proportion of CsCl·0.8PbCl₂ as its nominal composition and completely dissolved into a solvent water, to obtain a solution Q3 with a mass concentration of 50 g/L and containing a solute having a nominal composition of CsCl·0.8PbCl₂;
(2) SBA molecular sieve in certain mass was added to the solution Q3 obtained in the step (1) and stirred at 80° C. for 2 h to obtain a solution R3, where the mass ratio of the SBA molecular sieve to the solution Q3 was 0.2:1;
(3) the solution R3 obtained in the step (2) was evaporated at 80° C. until the solvent water was volatilized completely to obtain a powder G3;
(4) the powder G3 was calcined at 500° C. for 1 h to obtain a powder T3;
(5) the powder G3 was mixed with SrCl₂ in certain mass; the SrCl₂ was added according to a proportion of obtaining a solute having a nominal composition of CsCl·0.8PbCl₂·0.18SrCl₂ available, and then certain mass of water was added, and the mass ratio of the powder T3 to water was 1:2, a solution Q3-2 was then obtained;
(6) the solution Q3-2 was stirred for 1 h at room temperature and centrifuged at 2,500 rmp to obtain a precipitate H3; and
(7) the precipitate H3 was placed into an 80° C. oven and dried for 12 h, to obtain a material.

The material obtained in Comparative Example 3 was measured by a fluorescence spectrophotometer; under the excitation of a 365 nm blue ray, the material failed to give out light; the material obtained in Comparative Example 3 was heated up to 125° C. and its luminescent intensity was then measured and found to not give out light; 1 g of the material obtained in Comparative Example 3 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 3 was radiated by a blue ray having a power density of 150 mW/cm² and a wavelength of 365 nm for 24 h, it was found to not give out light. Test data of Comparative Example 3 is shown in Table 1.

### Comparative Example 4

A method for preparing a luminescent material provided in this comparative example includes the following specific steps:
(1) CsCl and PbCl₂ were heated at 80° C. in a proportion of CsCl·0.8PbCl₂ as its nominal composition and completely dissolved into a solvent water, to obtain a solution Q4 with a mass concentration of 50 g/L and containing a solute having a nominal composition of CsCl·0.8PbCl₂;
(2) SBA molecular sieve in certain mass was added to the solution Q4 obtained in the step (1) and stirred at 80° C. for 2 h to obtain a solution R4, where the mass ratio of the SBA molecular sieve to the solution Q4 was 0.2:1;
(3) the solution R4 obtained in the step (2) was evaporated at 80° C. until the solvent water was volatilized completely to obtain a powder G4;
(4) the powder G3 was calcined at 500° C. for 1 h to obtain a powder T4;
(5) the powder G4 was mixed with SrCl₂ in certain mass; the SrCl₂ was added according to a proportion of obtaining a solute having a nominal composition of CsCl·0.8PbCl₂·0.18SrCl₂ available, and then certain mass of water was added, and the mass ratio of the powder T4 to water was 1:2, a solution Q4-2 was then obtained;
(6) the solution Q4-2 was stirred for 1 h at room temperature and centrifuged at 2,500 rmp to obtain a precipitate H4; and
(7) the precipitate H4 was placed into an 80° C. oven and dried for 12 h, to obtain a powder G4-2; and
(8) the powder G4-2 was calcined at 500° C. for 1 h to obtain a material.

The material obtained in Comparative Example 4 was measured by a fluorescence spectrophotometer; under the excitation of a 365 nm blue ray, the material failed to give out light; the material obtained in Comparative Example 4 was heated up to 125° C. and its luminescent intensity was then measured and found to not give out light; 1 g of the material obtained in Comparative Example 4 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 4 was radiated by a blue ray having a power density of 150 mW/cm² and a wavelength of 365 nm for 24 h, it was found to not give out light. Test data of Comparative Example 4 is shown in Table 1.

### Comparative Example 5

A method for preparing a luminescent material provided in this comparative example includes the following specific steps:
(1) CsCl and PbCl₂ were heated at 80° C. in a proportion of CsCl·0.8PbCl₂ as its nominal composition and completely dissolved into a solvent water, to obtain a solution Q5 with a mass concentration of 50 g/L and containing a solute having a nominal composition of CsCl·0.8PbCl₂;
(2) SBA molecular sieve in certain mass was added to the solution Q5 obtained in the step (1) and stirred at 80° C. for 2 h to obtain a solution R5, where the mass ratio of the SBA molecular sieve to the solution Q5 was 0.2:1;
(3) the solution R5 obtained in the step (2) was evaporated at 80° C. until the solvent water was volatilized completely to obtain a powder 05;
(4) the powder G5 was calcined at 500° C. for 1 h to obtain a powder T5;
(5) the powder T5 was added to a certain volume of water, stirred at room temperature for 1 h, and then centrifuged at 2,500 rmp to obtain a precipitate H5, where the mass ratio of powder T5 to water is 1:2;
(6) the precipitate H5 was mixed with SrCl₂ in certain mass; the SrCl₂ was added according to a proportion of obtaining a solute having a nominal composition of CsCl·0.8PbCl₂·0.18SrCl₂ available, and then certain mass of water was added, and the mass ratio of the precipitate H5 to water was 1:2, a solution Q5-2 was then obtained;
(7) the solution Q5-2 was stirred for 1 h at room temperature and centrifuged at 2,500 rmp to obtain a precipitate 115-2; and
(8) the precipitate H5-2 was placed into an 80° C. oven and dried for 12 h, to obtain a material.

The material obtained in Comparative Example 5 was measured by a fluorescence spectrophotometer; under the excitation of a 365 nm blue ray, the material failed to give out light; the material obtained in Comparative Example 5 was heated up to 125° C. and its luminescent intensity was then measured and found to not give out light; 1 g of the material obtained in Comparative Example 5 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 5 was radiated by a blue ray having a power density of 150 mW/cm² and a wavelength of 365 nm for 24 h, it was found to not give out light. Test data of Comparative Example 5 is shown in Table 1.

### Comparative Example 6

A method for preparing a luminescent material provided in this comparative example includes the following specific steps:
(1) CsCl and PbCl₂ were heated at 80° C. in a proportion of CsCl·0.8PbCl₂ as its nominal composition and completely dissolved into a solvent water, to obtain a solution Q6 with a mass concentration of 50 g/L and a solute having a nominal composition of CsCl·0.8PbCl₂.
(2) SBA molecular sieve in certain mass was added to the solution Q6 obtained in the step (1) and stirred to obtain a solution R6, where the mass ratio of the SBA molecular sieve to the solution Q6 was 0.2:1;
(3) the solution R6 obtained in the step (2) was evaporated at 80° C. until the solvent water was volatilized completely to obtain a powder G6;
(4) the powder G6 was calcined at 500° C. for 1 h to obtain a powder T6;
(5) the powder T6 was added to a certain volume of water, stirred at room temperature for 1 h, and then centrifuged at 2,500 rmp to obtain a precipitate H6, where the mass ratio of powder T6 to water is 1:2;
(6) the precipitate 1-S-2 was placed into an 80° C. oven and dried for 12 h, to obtain a powder T6-2; and
(7) the powder T6-2 was mixed with SrCl₂ in certain mass; the SrCl₂ was added according to a proportion of obtaining a solute having a nominal composition of CsCl·0.8PbCl₂·0.18SrCl₂ available, and then certain mass of water was added, and the mass ratio of the powder T6-2 to water was 1:2, a solution Q6-2 was then obtained;
(8) the solution Q6-2 was stirred for 1 h at room temperature and centrifuged at 2,500 rmp to obtain a precipitate H6-2; and
(9) the precipitate H6-2 was placed into an 80° C. oven and dried for 12 h, to obtain a material.

The material obtained in Comparative Example 6 was measured by a fluorescence spectrophotometer; under the excitation of a 365 nm blue ray, the material failed to give out light; the material obtained in Comparative Example 6 was heated up to 125° C. and its luminescent intensity was then measured and found to not give out light; 1 g of the material obtained in Comparative Example 6 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 6 was radiated by a blue ray having a power density of 150 mW/cm² and a wavelength of 365 nm for 24 h, it was found to not give out light. Test data of Comparative Example 6 is shown in Table 1.

### Comparative Example 7

A method for preparing a luminescent material provided in this comparative example includes the following specific steps:
(1) CsCl and PbCl₂ were heated at 80° C. in a proportion of CsCl·0.8PbCl₂ as its nominal composition and completely dissolved into a solvent water, to obtain a solution Q7 with a mass concentration of 50 g/L and a solute having a nominal composition of CsCl·0.8PbCl₂.
(2) the solution Q7 obtained in the step (1) was evaporated at 80° C. until the solvent water was volatilized completely to obtain a powder G7;
(3) SrCl₂ in certain mass was added to the G7 and a certain volume of water was added; the SrCl₂ was added according to a proportion of obtaining a solute having a nominal composition of CsCl·0.8PbCl₂·0.18SrCl₂ available, and then stirred at 80° C. for 2 h to obtain a solution R7;
(4) SBA molecular sieve in certain mass was added to the solution R7 obtained in the step (3) and stirred at 80° C. for 2 h to obtain a solution R7-2, where the mass ratio of the SBA molecular sieve to the solution R7 was 0.2:1;
(5) the solution R7-2 obtained in the step (4) was evaporated at 80° C. until the solvent water was volatilized completely to obtain a powder G7;
(6) the powder G7 was calcined at 500° C. for 1 h to obtain a powder T7;
(7) the powder T7 was added to a certain volume of water, stirred at room temperature for 1 h, and then centrifuged at 2,500 rmp to obtain a precipitate H7, where the mass ratio of powder T7 to water is 1:2; and
(8) the precipitate H7 was placed into an 80° C. oven and dried for 12 h, to obtain a material.

The material obtained in Comparative Example 7 was measured by a fluorescence spectrophotometer; under the excitation of a 365 nm blue ray, the material failed to give out light; the material obtained in Comparative Example 7 was heated up to 125° C. and its luminescent intensity was then measured and found to not give out light; 1 g of the material obtained in Comparative Example 7 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 7 was radiated by a blue ray having a power density of 150 mW/cm² and a wavelength of 365 nm for 24 h, it was found to not give out light. Test data of Comparative Example 7 is shown in Table 1.

### Comparative Example 8

A method for preparing a luminescent material provided in this comparative example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q8 with a mass concentration of 50 g/L and a solute having a nominal composition of CsCl·0.8PbCl₂·0.18SrCl₂.
(2) the solution Q8 obtained in the step (1) was evaporated at 80° C. until the solvent water was volatilized completely to obtain a powder G8;
(3) the powder G8 was calcined at 5(0° C. for 1 h to obtain a powder T8;
(4) the powder T8 was added to a certain volume of water, stirred at room temperature for 1 h, and then centrifuged at 2,500 rmp to obtain a precipitate H8, where the mass ratio of powder T5 to water is 1:2; and
(5) the precipitate H8 was placed into an 80° C. oven and dried for 12 h, to obtain a material.

The material obtained in Comparative Example 8 was measured by a fluorescence spectrophotometer; under the excitation of a 365 nm blue ray, the material hardly gave out light; the material obtained in Comparative Example 8 was heated up to 125° C. and its luminescent intensity was then measured and found to not give out light; 1 g of the material obtained in Comparative Example 8 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 8 was radiated by a blue ray having a power density of 150 mW/cm⁷ and a wavelength of 365 nm for 24 h, it was found to not give out light. Test data of Comparative Example 8 is shown in Table 1.

### Comparative Example 9

A method for preparing a luminescent material provided in this comparative example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q9 with a mass concentration of 50 g/L and a solute having a nominal composition of CSCl·0.18PbCl₂·0.18SrCl₂.
(2) SBA molecular sieve in certain mass was added to the solution Q9 obtained in the step (1) and stirred at 80° C. for 2 h to obtain a solution R9, where the mass ratio of the SBA molecular sieve to the solution Q9 was 0.2:1;
(3) the solution R9 was centrifuged at 2,540 rmp to obtain a precipitate H9; and
(4) the precipitate H9 was placed into an 80° C. oven and dried for 12 h, to obtain a material.

The material obtained in Comparative Example 9 was measured by a fluorescence spectrophotometer; under the excitation of a 365 nm blue ray, the material failed to give out light; the material obtained in Comparative Example 9 was heated up to 125° C. and its luminescent intensity was then measured and found to not give out light; 1 g of the material obtained in Comparative Example 9 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Moreover, after the material obtained in Comparative Example 9 was radiated by a blue ray having a power density of 150 mW/cm² and a wavelength of 365 nm for 24 h, it was found to not give out light. Test data of Comparative Example 9 is shown in Table 1.

### Comparative Example 10

A method for preparing a luminescent material provided in this comparative example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q10 with a mass concentration of 50 g/L and a solute having a nominal composition of CsCl·0.8PbCl₂·0.18SrCl₂.
(2) SBA molecular sieve in certain mass was added to the solution Q10 obtained in the step (1) and stirred at 80° C. for 2 h to obtain a solution R10, where the mass ratio of the SBA molecular sieve to the solution Q10 was 0.2:1;
(3) the solution R10 obtained in the step (2) was evaporated at 80° C. until the solvent water was volatilized completely to obtain a powder G10;
(4) the powder G10 was added to a certain volume of water, stirred at room temperature for 1 h, and then centrifuged at 2,500 rmp to obtain a precipitate H10, where the mass ratio of powder G10 to water is 1:2; and
(5) the precipitate H10 was placed into an 80° C. oven and dried for 12 h, to obtain a material.

The material obtained in Comparative Example 10 was measured by a fluorescence spectrophotometer; under the excitation of a 365 nm blue ray, the material hardly gave out light; the material obtained in Comparative Example 10 was heated up to 125° C. and its luminescent intensity was then measured and the material was found to hardly give out light; 1 g of the material obtained in Comparative Example 10 was taken and added to 100 g of water to detect the material stability, subjected to standing for 24 h and filtered with a filter paper; the substance on the filter paper was dried for 24 h at 80° C. and the dried material on the filter paper was measured by the fluorescence spectrophotometer, but found to not give out light. Moreover, after the material obtained in Comparative Example 10 was radiated by a blue ray having a power density of 150 mW/cm² and a wavelength of 365 nm for 24 h, it was found to hardly give out light. Test data of Comparative Example 10 is shown in Table 1.

### Comparative Example 11

A method for preparing a luminescent material provided in this comparative example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q11 with a mass concentration of 50 g/L and a solute having a nominal composition of CsCl·0.8PbCl₂·0.18SrCl₂.
(2) SBA molecular sieve in certain mass was added to the solution Q11 obtained in the step (1) and stirred at 80° C. for 2 h to obtain a solution R11, where the mass ratio of the SBA molecular sieve to the solution Q11 was 0.2:1;
(3) the solution R11 obtained in the step (2) was evaporated at 80° C. until the solvent water was volatilized completely to obtain a powder G11; and
(4) the powder G11 was calcined at 500° C. for 1 h to obtain a material.

The material obtained in Comparative Example 11 was measured by a fluorescence spectrophotometer; under the excitation of a 365 nm blue ray, the material has a moderate luminescent intensity; the material obtained in Comparative Example 11 was heated up to 125° C. and its luminescent intensity was then measured, and the material was then found to have only 20% of the measured value at room temperature; 1 g of the material obtained in Comparative Example 11 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 11 had very poor stability. After the material obtained in Comparative Example 11 was radiated by a blue ray having a power density of 150 mW/cm² and a wavelength of 365 nm for 24 h, its luminescent intensity declined in a proportion of greater than 80% of its initial value. Test data of Comparative Example 11 is shown in Table 1.

### Comparative Example 12

A method for preparing a luminescent material provided in this comparative example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q12 with a mass concentration of 50 g/L and a solute having a nominal composition of CsCl·0.8PbCl₂·0.18SrCl₂.
(2) SBA molecular sieve in certain mass was added to the solution Q12 obtained in the step (0) and stirred at 80° C. for 2 h to obtain a solution R12, where the mass ratio of the SBA molecular sieve to the solution Q12 was 0.2:1;
(3) the solution R12 obtained in the step (2) was evaporated at 80° C. until the solvent water was volatilized completely to obtain a powder 012; and
(4) the powder G12 was placed into an 80° C. oven and dried for 12 h, to obtain a material.

The material obtained in Comparative Example 12 was measured by a fluorescence spectrophotometer; under the excitation of a 365 nm blue ray, the material has a low luminescent intensity; the material obtained in Comparative Example 12 was heated up to 125° C. and its luminescent intensity was then measured, and the material was then found to have only 22% of the measured value at room temperature; 1 g of the material obtained in Comparative Example 12 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 12 had very poor stability. After the material obtained in Comparative Example 12 was radiated by a blue ray having a power density of 150 mW/cm² and a wavelength of 365 nm for 24 h, its luminescent intensity declined in a proportion of greater than 75% of its initial value. Test data of Comparative Example 12 is shown in Table 1.

### Comparative Example 13

A method for preparing a luminescent material provided in this comparative example includes the following specific steps:
(1) a chloroform solution Q13 dissolved with CsCl·PbCl₂ was prepared, and the CsCl·PbCl₂ had a mass concentration of 50 g/L;
(2) SBA molecular sieve in certain mass was added to the solution Q13 obtained in the step (1) and stirred at 80° C. for 2 h to obtain a solution R13, where the mass ratio of the SBA molecular sieve to the solution Q13 was 0.2:1;
(3) the solution R13 obtained in the step (2) was evaporated at 80° C. until the solvent chloroform was volatilized completely to obtain a powder G13; and
(4) the powder G13 was calcined at 500° C. for 1 h to obtain a powder T13;
(5) the powder T13 was added to a certain volume of water, stirred at room temperature for 1 h, and then centrifuged at 2,500 rmp to obtain a precipitate H13, where the mass ratio of powder T13 to water is 1:2; and
(6) the precipitate H13 was placed into an 80° C. oven and dried for 12 h, to obtain a material.

The material obtained in Comparative Example 13 was measured by a fluorescence spectrophotometer; under the excitation of a 365 nm blue ray, the material has a low luminescent intensity; the material obtained in Comparative Example 13 was heated up to 125° C. and its luminescent intensity was then measured, and the material was then found to have only 24% of the measured value at room temperature; 1 g of the material obtained in Comparative Example 13 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer and found to hardly give out light. Obviously, the material obtained in Comparative Example 13 had very poor stability. After the material obtained in Comparative Example 13 was radiated by a blue ray having a power density of 150 mW/cm² and a wavelength of 365 nm for 24 h, its luminescent intensity declined in a proportion of greater than 82% of its initial value. Test data of Comparative Example 13 is shown in Table 1.

### Comparative Example 14

A method for preparing a luminescent material provided in this comparative example includes the following specific steps:
(1) a chloroform solution Q14 dissolved with CsCl·PbCl₂ was prepared, and the CsCl·PbCl₂ had a mass concentration of 50 g/L;
(2) SBA molecular sieve in certain mass was added to the solution Q14 obtained in the step (1) and stirred at 80° C. for 2 h to obtain a solution R14, where the mass ratio of the SBA molecular sieve to the solution Q14 was 0.2:1;
(3) the solution R14 was filtered by a filter paper to obtain a powder G14 on the filter paper,
(4) the powder G14 was calcined at 500° C. for 1 h to obtain a powder T14; and (0184) (5) the powder T14 was added to a certain volume of water, stirred at room temperature for 1 h, and then centrifuged at 2,500 rmp to obtain a precipitate H14, where the mass ratio of powder T14 to water is 1:2; and
(6) the precipitate H14 was placed into an 80° C. oven and dried for 12 h, to obtain a material.

The material obtained in Comparative Example 14 was measured by a fluorescence spectrophotometer; under the excitation of a 365 nm blue ray, the material has a low luminescent intensity; the material obtained in Comparative Example 14 was heated up to 125° C. and its luminescent intensity was then measured, and the material was then found to have only 23% of the measured value at room temperature; 1 g of the material obtained in Comparative Example 14 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer and found to hardly give out light. Obviously, the material obtained in Comparative Example 14 had very poor stability. After the material obtained in Comparative Example 14 was radiated by a blue ray having a power density of 150 mW/cm² and a wavelength of 365 nm for 24 h, its luminescent intensity declined in a proportion of greater than 77% of its initial value. Test data of Comparative Example 14 is shown in Table 1.

### Comparative Example 15

A method for preparing a luminescent material provided in this comparative example includes the following specific steps:
(1) a chloroform solution Q15 dissolved with CsCl·PbCl₂ was prepared, and the CsCl·PbCl₂ had a mass concentration of 50 g/L;
(2) SBA molecular sieve in certain mass was added to the solution Q15 obtained in the step (1) and stirred at 80° C. for 2 h to obtain a solution R15, where the mass ratio of the SBA molecular sieve to the solution Q15 was 0.2:1;
(3) the solution R15 was filtered by a filter paper to obtain a powder G15 on the filter paper, and
(4) the powder G15 was calcined at 500° C. for 1 h to obtain a material.

The material obtained in Comparative Example 15 was measured by a fluorescence spectrophotometer; under the excitation of a 365 nm blue ray, the material has a low luminescent intensity; the material obtained in Comparative Example 15 was heated up to 125° C. and its luminescent intensity was then measured, and the material was then found to have only 21% of the measured value at room temperature; 1 g of the material obtained in Comparative Example 15 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 15 had very poor stability. After the material obtained in Comparative Example 15 was radiated by a blue ray having a power density of 150 mW/cm² and a wavelength of 365 nm for 24 h. its luminescent intensity declined in a proportion of greater than 69% of its initial value. Test data of Comparative Example 15 is shown in Table 1.

### Comparative Example 16

A method for preparing a luminescent material provided in this comparative example includes the following specific steps:
(1) a chloroform solution Q16 dissolved with CsCl·PbCl₂ was prepared, and the CsCl·PbCl₂ had a mass concentration of 50 g/L;
(2) SBA molecular sieve in certain mass was added to the solution Q16 obtained in the step (1) and stirred at 80° C. for 2 h to obtain a solution R16, where the mass ratio of the SBA molecular sieve to the solution Q16 was 0.2:1; and
(3) the solution R16 was directly put to a muffle furnace, heated up from room temperature at a heating rate of 10° C./min, and finally calcined at 500° C. for 1 h to obtain a material.

The material obtained in Comparative Example 16 was measured by a fluorescence spectrophotometer; under the excitation of a 365 nm blue ray, the material has a low luminescent intensity; the material obtained in Comparative Example 16 was heated up to 125° C. and its luminescent intensity was then measured, and the material was then found to have only 24% of the measured value at room temperature; 1 g of the material obtained in Comparative Example 16 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 16 had very poor stability. After the material obtained in Comparative Example 16 was radiated by a blue ray having a power density of 150 mW/cm² and a wavelength of 365 nm for 24 h, its luminescent intensity declined in a proportion of greater than 65% of its initial value. Test data of Comparative Example 16 is shown in Table 1.

### Comparative Example 17

A method for preparing a luminescent material provided in this comparative example includes the following specific steps:
(1) a chloroform solution Q17 dissolved with CsCl·PbCl₂ was prepared, and the CsCl·PbCl₂ had a mass concentration of 50 g/L;
(2) SBA molecular sieve in certain mass was added to the solution Q17 obtained in the step (1) and stirred at 80° C. for 2 h to obtain a solution R17, where the mass ratio of the SBA molecular sieve to the solution Q17 was 0.2:1; and
(3) the solution R17 was placed into an 80° C. oven and dried for 12 h, to obtain a material.

The material obtained in Comparative Example 17 was measured by a fluorescence spectrophotometer; under the excitation of a 365 nm blue ray, the material has a low luminescent intensity; the material obtained in Comparative Example 17 was heated up to 125° C. and its luminescent intensity was then measured, and the material was then found to have only 23% of the measured value at room temperature; 1 g of the material obtained in Comparative Example 17 was taken and added to 100 g of water to detect the material stability, subjected to standing for 24 h and filtered with a filter paper; the substance on the filter paper was dried for 24 h at 8 W° C., and the dried material on the filter paper was measured by the fluorescence spectrophotometer, and the luminescent intensity was found to be extremely low. Obviously, the material obtained in Comparative Example 17 had very poor stability. After the material obtained in Comparative Example 17 was radiated by a blue ray having a power density of 150 mW/cm² and a wavelength of 365 nm for 24 h. its luminescent intensity declined in a proportion of greater than 69% of its initial value. Test data of Comparative Example 17 is shown in Table 1.

### Comparative Example 18

A method for preparing a luminescent material provided in this comparative example includes the following specific steps:
(1) a chloroform solution QIS dissolved with CsCl·PbCl₂ was prepared, and the CsCl·PbCl₂ had a mass concentration of 50 g/L;
(2) SrCl₂ in certain mass was added to the solution Q18 according to a proportion of obtaining a solute having a nominal composition of CsCl·PbCl₂·0.18SrCl₂ available, and stirred at 80° C. for 2 h to obtain a solution R18;
(3) certain mass of SBA molecular sieve was added to the solution R18 obtained in the step (1) and stirred at 80′C for 2 h to obtain a solution R18-2, where the mass ratio of the SBA molecular sieve to the solution R18 was 0.2:1;
(4) the solution R18-2 was filtered by a filter paper to obtain a powder G18 on the filter paper, and
(5) the powder G18 was calcined at 500° C. for 1 h to obtain a powder T18;
(6) the powder T18 was added to a certain volume of water, stirred at room temperature for 1 h, and then centrifuged at 2,500 rmp to obtain a precipitate H18, where the mass ratio of powder T18 to water is 1:2; and
(7) the precipitate H18 was placed into an 80° C. oven and dried for 12 h, to obtain a material.

The material obtained in Comparative Example 18 was measured by a fluorescence spectrophotometer; under the excitation of a 365 nm blue ray, the material has a low luminescent intensity; the material obtained in Comparative Example 18 was heated up to 125° C. and its luminescent intensity was then measured, and the material was then found to have only 22% of the measured value at room temperature; 1 g of the material obtained in Comparative Example 18 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 18 had very poor stability. After the material obtained in Comparative Example 18 was radiated by a blue ray having a power density of 150 mW/cm² and a wavelength of 365 nm for 24 h, its luminescent intensity declined in a proportion of greater than 69% of its initial value. Test data of Comparative Example 18 is shown in Table 1.

### Comparative Example 19

A method for preparing a luminescent material provided in this comparative example includes the following specific steps:
(1) a chloroform solution Q19 dissolved with CsCl·PbCl₂ was prepared, and the CsCl·PbCl₂ had a mass concentration of 50 g/L;
(2) SrCl₂ in certain mass was added to the solution Q19 according to a proportion of obtaining a solute having a nominal composition of CsCl·PbCl₂·0.18SrCl₂ available, and stirred at 80° C. for 2 h to obtain a solution R19;
(3) the solution R19 was placed into an 80° C. oven and dried for 12 h, to obtain a powder G19;
(4) the powder G19 was added to a certain volume of water, stirred at room temperature for 1 h, and then centrifuged at 2,500 rmp to obtain a precipitate H19, where the mass ratio of powder G19 to water is 1:2; and
(5) the precipitate H19 was placed into an 80° C. oven and dried for 12 h, to obtain a material.

The material obtained in Comparative Example 19 was measured by a fluorescence spectrophotometer; under the excitation of a 365 nm blue ray, the material had a very weak luminescent intensity; the material obtained in Comparative Example 19 was heated up to 125° C. and its luminescent intensity was then measured and found to not give out light; 1 g of the material obtained in Comparative Example 19 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, but found to not give out light. Obviously, the material obtained in Comparative Example 19 had very poor stability. Moreover, after the material obtained in Comparative Example 19 was radiated by a blue ray having a power density of 150 mW/cm, and a wavelength of 365 nm for 24 h, it was found to not give out light. Test data of Comparative Example 19 is shown in Table 1.

### Comparative Example 20

A method for preparing a luminescent material provided in this comparative example includes the following specific steps:
(1) a chloroform solution Q20 dissolved with CsCl·PbCl₂ was prepared, and the CsCl·PbCl₂ had a mass concentration of 50 g/L;
(2) SrCl₂ in certain mass was added to the solution Q20 according to a proportion of obtaining a solute having a nominal composition of CsCl·PbCl₂·0.18SrCl₂ available, and stirred at 80° C. for 2 h to obtain a solution R20;
(3) certain mass of SBA molecular sieve was added to the solution R20 obtained in the step (2) and stirred at 80′C for 2 h to obtain a solution R20-2, where the mass ratio of the SBA molecular sieve to the solution R20 was 0.2:1;
(4) the solution R20-2 was placed into an 80° C. oven and dried for 12 h, to obtain a powder G20;
(5) the powder G20 was added to a certain volume of water, stirred at room temperature for 1 h, and then centrifuged at 2,500 rmp to obtain a precipitate H20, where the mass ratio of powder G20 to water is 1:2; and
(6) the precipitate H20 was placed into an 80° C. oven and dried for 12 h, to obtain a material.

The material obtained in Comparative Example 20 was measured by a fluorescence spectrophotometer; under the excitation of a 365 nm blue ray, the material has a low luminescent intensity; the material obtained in Comparative Example 20 was heated up to 125° C. and its luminescent intensity was then measured, and the material was then found to have only 27% of the measured value at room temperature; 1 g of the material obtained in Comparative Example 20 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 20 had very poor stability. After the material obtained in Comparative Example 20 was radiated by a blue ray having a power density of 150 mW/cm² and a wavelength of 365 nm for 24 h, its luminescent intensity declined in a proportion of greater than 73% of its initial value. Test data of Comparative Example 20 is shown in Table 1.

### Comparative Example 21

A method for preparing a luminescent material provided in this comparative example includes the following specific steps:
(1) a chloroform solution Q20 dissolved with CsCl·PbCl₂ was prepared, and the CsCl·PbCl₂ had a mass concentration of 50 g/L;
(2) SrCl₂ in certain mass was added to the solution Q20 according to a proportion of obtaining a solute having a nominal composition of CsCl·PbCl₂·0.18SrCl₂ available, and stirred at 80° C. for 2 h to obtain a solution R21;
(3) SBA molecular sieve in certain mass was added to the solution R20 obtained in the step (2) and stirred at 80° C. for 2 h to obtain a solution R21-2, where the mass ratio of the SBA molecular sieve to the solution R21 was 0.2:1;
(4) the solution R21-2 was placed into an 80° C. oven and dried for 12 h, to obtain a powder G21; and
(5) the powder G21 was calcined at 500° C. for 1 h to obtain a material.

The material obtained in Comparative Example 21 was measured by a fluorescence spectrophotometer; under the excitation of a 365 nm blue ray, the material has a low luminescent intensity; the material obtained in Comparative Example 21 was heated up to 125° C. and its luminescent intensity was then measured, and the material was then found to have only 21% of the measured value at room temperature; 1 g of the material obtained in Comparative Example 21 was taken and added to 100 g of water to detect the material stability, subjected to standing for 24 h and filtered with a filter paper; the substance on the filter paper was dried for 24 h at 8 W° C., and the dried material on the filter paper was measured by the fluorescence spectrophotometer, and the luminescent intensity was found to be extremely low. Obviously, the material obtained in Comparative Example 21 had very poor stability. After the material obtained in Comparative Example 21 was radiated by a blue ray having a power density of 150 mW/cm² and a wavelength of 365 nm for 24 h. its luminescent intensity declined in a proportion of greater than 71% of its initial value. Test data of Comparative Example 21 is shown in Table 1.

### Comparative Example 22

A method for preparing a luminescent material provided in this comparative example includes the following specific steps:
(1) a chloroform solution Q22 dissolved with CsCl·PbCl₂ was prepared, and the CsCl·PbCl₂ had a mass concentration of 50 g/L;
(2) SrCl₂ in certain mass was added to the solution Q22 according to a proportion of obtaining a solute having a nominal composition of CsCl·PbCl₂·0.18SrCl₂ available, and stirred at 80° C. for 2 h to obtain a solution R22;
(3) certain mass of SBA molecular sieve was added to the solution R22 obtained in the step (2) and stirred at 80′C for 2 h to obtain a solution R22-2, where the mass ratio of the SBA molecular sieve to the solution R22 was 0.2:1; and
(4) the solution R22-2 was placed into an 80° C. oven and dried for 12 h, to obtain a material.

The material obtained in Comparative Example 22 was measured by a fluorescence spectrophotometer; under the excitation of a 365 nm blue ray, the material has a low luminescent intensity; the material obtained in Comparative Example 22 was heated up to 125° C. and its luminescent intensity was then measured, and the material was then found to have only 22% of the measured value at room temperature; 1 g of the material obtained in Comparative Example 22 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 22 had very poor stability. After the material obtained in Comparative Example 22 was radiated by a blue ray having a power density of 150 mW/cm² and a wavelength of 365 nm for 24 h, its luminescent intensity declined in a proportion of greater than 78% of its initial value. Test data of Comparative Example 22 is shown in Table 1.

### Comparative Example 23

A method for preparing a luminescent material provided in this comparative example includes the following specific steps:
(1) a chloroform solution Q23 dissolved with CSCl·PbCl₂ was prepared, and the CsCl·PbCl₂ had a mass concentration of 50 g/L;
(2) SBA molecular sieve in certain mass was added to the solution Q23 and stirred at 80° C. for 2 h to obtain a solution Q23-2, where the mass ratio of the SBA molecular sieve to the solution Q23 was 0.2:1;
(3) SrCl₂ in certain mass was added to the solution Q23-2 according to a proportion of obtaining a solute having a nominal composition of CsCl·PbCl₂·0.18SrCl₂ available, and stirred at 80° C. for 2 h to obtain a solution R23;
(4) the solution R23 was placed into an 80° C. oven and dried for 12 h, to obtain a powder G23;
(5) the powder G23 was calcined at 500° C. for 1 h to obtain a powder T23;
(6) the powder T23 was added to a certain volume of water, stirred at room temperature for 1 h, and then centrifuged at 2,500 rmp to obtain a precipitate H23, where the mass ratio of powder T23 to water is 1:2; and
(7) the precipitate H23 was placed into an 80° C. oven and dried for 12 h, to obtain a material.

The material obtained in Comparative Example 23 was measured by a fluorescence spectrophotometer; under the excitation of a 365 nm blue ray, the material has a low luminescent intensity, the material obtained in Comparative Example 23 was heated up to 125° C. and its luminescent intensity was then measured, and the material was then found to have only 24% of the measured value at room temperature; 1 g of the material obtained in Comparative Example 23 was taken and added to 100 g of water to detect the material stability, subjected to standing for 24 h and filtered with a filter paper; the substance on the filter paper was dried for 24 h at 8 W° C., and the dried material on the filter paper was measured by the fluorescence spectrophotometer, and the luminescent intensity was found to be extremely low. Obviously, the material obtained in Comparative Example 23 had very poor stability. After the material obtained in Comparative Example 23 was radiated by a blue ray having a power density of 150 mW/cm² and a wavelength of 365 nm for 24 h, its luminescent intensity declined in a proportion of greater than 66% of its initial value. Test data of Comparative Example 23 is shown in Table 1.

### Comparative Example 24

A method for preparing a luminescent material provided in this comparative example includes the following specific steps:
(1) a chloroform solution Q24 dissolved with CsCl·PbCl₂ was prepared, and the CsCl·PbCl₂ had a mass concentration of 50 g/L;
(2) SBA molecular sieve in certain mass was added to the solution Q24 and stirred at 80° C. for 2 h to obtain a solution Q24-2, where the mass ratio of the SBA molecular sieve to the solution Q24 was 0.2:1;
(3) the solution Q24-2 was placed into an 80° C. oven and dried for 12 h, to obtain a powder G24;
(4) the powder G23 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R24;
(5) the solution R24 was placed into an 80° C. oven and dried for 12 h, to obtain a powder G24;
(6) the powder G24 was calcined at 500° C. for 1 h to obtain a powder T24;
(7) the powder T24 was added to a certain volume of water, stirred at room temperature for 1 h, and then centrifuged at 2,500 rmp to obtain a precipitate H24, where the mass ratio of powder T24 to water is 1:2; and
(8) the precipitate H24 was placed into an 80° C. oven and dried for 12 h, to obtain a material.

The material obtained in Comparative Example 24 was measured by a fluorescence spectrophotometer; under the excitation of a 365 nm blue ray, the material has a low luminescent intensity; the material obtained in Comparative Example 24 was heated up to 125° C. and its luminescent intensity was then measured, and the material was then found to have only 25% of the measured value at room temperature; 1 g of the material obtained in Comparative Example 24 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 24 had very poor stability. After the material obtained in Comparative Example 24 was radiated by a blue ray having a power density of 150 mW/cm² and a wavelength of 365 nm for 24 h, its luminescent intensity declined in a proportion of greater than 69% of its initial value. Test data of Comparative Example 24 is shown in Table 1.

### Comparative Example 25

A method for preparing a luminescent material provided in this comparative example includes the following specific steps:
(1) a chloroform solution Q25 dissolved with CsCl·PbCl₂ was prepared, and the CsCl·PbCl₂ had a mass concentration of 50 g/L;
(2) SBA molecular sieve in certain mass was added to the solution Q25 and stirred at 80° C. for 2 h to obtain a solution Q25-2, where the mass ratio of the SBA molecular sieve to the solution Q25 was 0.2:1;
(3) the solution Q25-2 was placed into an 80° C. oven and dried for 12 h, to obtain a powder G25;
(4) the powder G25 was calcined at 500° C. for 1 h to obtain a powder T25; and
(5) the powder T25 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R25;
(6) the solution R25 was placed into an 80° C. oven and dried for 12 h, to obtain a powder G25;
(7) the powder T25 was added to a certain volume of water, stirred at room temperature for 1 h. and then centrifuged at 2,500 rmp to obtain a precipitate H25, where the mass ratio of powder T25 to water is 1:2; and
(8) the precipitate H25 was placed into an 80° C. oven and dried for 12 h, to obtain a material.

The material obtained in Comparative Example 25 was measured by a fluorescence spectrophotometer; under the excitation of a 365 nm blue ray, the material has a low luminescent intensity; the material obtained in Comparative Example 25 was heated up to 125° C. and its luminescent intensity was then measured, and the material was then found to have only 25% of the measured value at room temperature; 1 g of the material obtained in Comparative Example 25 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 25 had very poor stability. After the material obtained in Comparative Example 25 was radiated by a blue ray having a power density of 150 mW/cm² and a wavelength of 365 nm for 24 h, its luminescent intensity declined in a proportion of greater than 72% of its initial value. Test data of Comparative Example 25 is shown in Table 1.

### Comparative Example 26

A method for preparing a luminescent material provided in this comparative example includes the following specific steps:
(1) a chloroform solution Q26 dissolved with CsCl·PbCl₂ was prepared, and the CsCl·PbCl₂ had a mass concentration of 50 g/L;
(2) SBA molecular sieve in certain mass was added to the solution Q26 and stirred at 80° C. for 2 h to obtain a solution Q26-2, where the mass ratio of the SBA molecular sieve to the solution Q26 was 0.2:1;
(3) the solution Q26-2 was placed into an 80° C. oven and dried for 12 h, to obtain a powder G26;
(4) the powder G26 was calcined at 500° C. for 1 h to obtain a powder T26; and
(5) the powder T26 was added to a certain volume of water, stirred at room temperature for 1 h, and then centrifuged at 2,500 rmp to obtain a precipitate H26, where the mass ratio of powder T26 to water is 1:2; and
(6) the precipitate H26 was placed into an 80° C. oven and dried for 12 h, to obtain a powder G26-2; and
(7) the powder G26-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R26;
(8) the solution R26 was placed into an 80° C. oven and dried for 12 h, to obtain a powder G26-3;
(9) the powder G26-3 was calcined at 5° C. for 1 h to obtain a powder T26-2; and
(10) the powder T26-2 was added to a certain volume of water, stirred at room temperature for 1 h, and then centrifuged at 2,500 rmp to obtain a precipitate H26-2, where the mass ratio of powder T26-2 to water is 1:2; and
(11) the precipitate 1126-2 was placed into an 80° C. oven and dried for 12 h, to obtain a material.

The material obtained in Comparative Example 26 was measured by a fluorescence spectrophotometer; under the excitation of a 365 nm blue ray, the material has a low luminescent intensity; the material obtained in Comparative Example 26 was heated up to 125° C. and its luminescent intensity was then measured, and the material was then found to have only 22% of the measured value at room temperature; 1 g of the material obtained in Comparative Example 26 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 26 had very poor stability. After the material obtained in Comparative Example 26 was radiated by a blue ray having a power density of 150 mW/cm² and a wavelength of 365 nm for 24 h, its luminescent intensity declined in a proportion of greater than 73% of its initial value. Test data of Comparative Example 26 is shown in Table 1.

### Comparative Example 27

A method for preparing a luminescent material provided in this comparative example includes the following specific steps:
(1) a chloroform solution Q27 dissolved with CsCl·PbCl₂ was prepared, and the CsCl·PbCl₂ had a mass concentration of 50 g/L;
(2) SBA molecular sieve in certain mass was added to the solution Q27 and stirred at 80° C. for 2 h to obtain a solution Q27-2, where the mass ratio of the SBA molecular sieve to the solution Q27 was 0.2:1;
(3) the solution Q27-2 was placed into an 80° C. oven and dried for 12 h, to obtain a powder G27;
(4) the powder G27 was calcined at 500° C. for 1 h to obtain a powder T27; and
(5) the powder T27 was added to a certain volume of water, stirred at room temperature for 1 h, and then centrifuged at 2,500 rmp to obtain a precipitate H27, where the mass ratio of powder T27 to water is 1:2;
(6) the precipitate H27 was placed into an 80° C. oven and dried for 12 h, to obtain a powder G27-2; and
(7) the powder G27-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R27;
(8) the solution R27 was filtered by a filter paper to obtain a powder G27-3 on the filter paper; and
(9) the powder G27-3 was calcined at 500° C. for 1 h to obtain a powder T27-2; and
(10) the powder T27-2 was added to a certain volume of water, stirred at room temperature for 1 h, and then centrifuged at 2,500 rmp to obtain a precipitate H27-2, where the mass ratio of powder T27-2 to water is 1:2; and
(11) the precipitate H27-2 was placed into an 80° C. oven and dried for 12 h, to obtain a material.

The material obtained in Comparative Example 27 was measured by a fluorescence spectrophotometer; under the excitation of a 365 nm blue ray, the material has a low luminescent intensity; the material obtained in Comparative Example 27 was heated up to 125° C. and its luminescent intensity was then measured, and the material was then found to have only 11% of the measured value at room temperature; 1 g of the material obtained in Comparative Example 27 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 27 had very poor stability. After the material obtained in Comparative Example 27 was radiated by a blue ray having a power density of 150 mW/cm² and a wavelength of 365 nm for 24 h, its luminescent intensity declined in a proportion of greater than 75% of its initial value. Test data of Comparative Example 27 is shown in Table 1.

### Comparative Example 28

A method for preparing a luminescent material provided in this comparative example includes the following specific steps:
(1) a chloroform solution Q28 dissolved with CsCl·PbCl₂ was prepared, and the CsCl·PbCl₂ had a mass concentration of 50 g/L;
(2) SBA molecular sieve in certain mass was added to the solution Q28 and stirred at 80′C for 2 h to obtain a solution Q28-2, where the mass ratio of the SBA molecular sieve to the solution Q28 was 0.2:1;
(3) the solution Q28-2 was placed into an 80° C. oven and dried for 12 h, to obtain a powder G28;
(4) the powder G28 was calcined at 500° C. for 1 h to obtain a powder T28; and
(5) the powder T28 was added to a certain volume of water, stirred at room temperature for 1 h, and then centrifuged at 2,500 rmp to obtain a precipitate H28, where the mass ratio of powder T28 to water is 1:2;
(6) the precipitate H28 was placed into an 80° C. oven and dried for 12 h, to obtain a powder G28-2; and
(7) the powder G28-2 and SrCl₂ in certain mass were added to water, the SrCl₂ was added according to a proportion of obtaining a solute having a nominal composition of CsCl·PbCl₂·0.18SrCl₂ available, and stirred at 80° C. for 2 h to obtain a solution R28;
(8) the solution R28 was filtered by a filter paper to obtain a powder G28-3 on the filter paper;
(9) the powder G28-3 was added to a certain volume of water, stirred at room temperature for 1 h, and then centrifuged at 2,500 rmp to obtain a precipitate H28-2, where the mass ratio of powder T28-2 to water is 1:2; and
(10) the precipitate H28-2 was placed into an 80° C. oven and dried for 12 h, to obtain a material.

The material obtained in Comparative Example 28 was measured by a fluorescence spectrophotometer; under the excitation of a 365 nm blue ray, the material has a low luminescent intensity; the material obtained in Comparative Example 28 was heated up to 125° C. and its luminescent intensity was then measured, and the material was then found to have only 21% of the measured value at room temperature; 1 g of the material obtained in Comparative Example 28 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 28 had very poor stability. After the material obtained in Comparative Example 28 was radiated by a blue ray having a power density of 150 mW/cm² and a wavelength of 365 nm for 24 h, its luminescent intensity declined in a proportion of greater than 74% of its initial value. Test data of Comparative Example 28 is shown in Table 1.

### Comparative Example 29

A method for preparing a luminescent material provided in this comparative example includes the following specific steps:
(1) a chloroform solution Q29 dissolved with CsCl·PbCl₂ was prepared, and the CsCl·PbCl₂ had a mass concentration of 50 g/L;
(2) SBA molecular sieve in certain mass was added to the solution Q29 and stirred at 80° C. for 2 h to obtain a solution Q29-2, where the mass ratio of the SBA molecular sieve to the solution Q29 was 0.2:1;
(3) the solution Q29-2 was placed into an 80° C. oven and dried for 12 h, to obtain a powder 029;
(4) the powder 029 was calcined at 500° C. for 1 h to obtain a powder T29; and
(5) the powder T29 was added to a certain volume of water, stirred at room temperature for 1 h, and then centrifuged at 2,500 rmp to obtain a precipitate H29, where the mass ratio of powder T29 to water is 1:2;
(6) the precipitate H29 was placed into an 80° C. oven and dried for 12 h, to obtain a powder G29-2; and
(7) the powder G29-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R29;
(8) the solution R29 was filtered by a filter paper to obtain a powder G29-3 on the filter paper;
(9) the powder G29-3 was added to a certain volume of water, stirred at room temperature for 1 h, and then centrifuged at 2,500 rmp to obtain a precipitate H29-2, where the mass ratio of powder 029-3 to water is 1:2; and
(10) the precipitate H29-2 was placed into an 80° C. oven and dried for 12 h, to obtain a material.

The material obtained in Comparative Example 29 was measured by a fluorescence spectrophotometer; under the excitation of a 365 nm blue ray, the material has a low luminescent intensity; the material obtained in Comparative Example 29 was heated up to 125° C. and its luminescent intensity was then measured, and the material was then found to have only 22% of the measured value at room temperature; 1 g of the material obtained in Comparative Example 29 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 29 had very poor stability. After the material obtained in Comparative Example 29 was radiated by a blue ray having a power density of 150 mW/cm² and a wavelength of 365 nm for 24 h, its luminescent intensity declined in a proportion of greater than 77% of its initial value. Test data of Comparative Example 29 is shown in Table 1.

### Comparative Example 30

A method for preparing a luminescent material provided in this comparative example includes the following specific steps:
(1) a chloroform solution Q27 dissolved with CsCl·PbCl₂ was prepared, and the CsCl·PbCl₂ had a mass concentration of 50 g/L;
(2) SBA molecular sieve in certain mass was added to the solution Q27 and stirred at 80° C. for 2 h to obtain a solution Q27-2, where the mass ratio of the SBA molecular sieve to the solution Q27 was 0.2:1;
(3) the solution Q27-2 was placed into an 80° C. oven and dried for 12 h, to obtain a powder G27;
(4) the powder G27 was calcined at 500° C. for 1 h to obtain a powder T27; and
(5) the powder T27 was added to a certain volume of water, stirred at room temperature for 1 h, and then centrifuged at 2,500 rmp to obtain a precipitate H27, where the mass ratio of powder T27 to water is 1:2;
(6) the precipitate 127 was placed into an 80° C. oven and dried for 12 h, to obtain a powder G27-2; and
(7) the powder G27-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R27;
(8) the solution R27 was filtered by a filter paper to obtain a powder G27-3 on the filter paper, and
(9) the powder G27-3 was calcined at 500° C. for 1 h to obtain a material.

The material obtained in Comparative Example 30 was measured by a fluorescence spectrophotometer; under the excitation of a 365 nm blue ray, the material has a low luminescent intensity; the material obtained in Comparative Example 30 was heated up to 125° C. and its luminescent intensity was then measured, and the material was then found to have only 24% of the measured value at room temperature; 1 g of the material obtained in Comparative Example 30 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 30 had very poor stability. After the material obtained in Comparative Example 30 was radiated by a blue ray having a power density of 150 mW/cm² and a wavelength of 365 nm for 24 h, its luminescent intensity declined in a proportion of greater than 72% of its initial value. Test data of Comparative Example 30 is shown in Table 1.

### Comparative Example 31

A method for preparing a luminescent material provided in this comparative example includes the following specific steps:
(1) a chloroform solution Q31 dissolved with CsCl·PbCl₂ was prepared, and the CsCl·PbCl₂ had a mass concentration of 50 g/L;
(2) SBA molecular sieve in certain mass was added to the solution Q31 and stirred at 80° C. for 2 h to obtain a solution Q31-2, where the mass ratio of the SBA molecular sieve to the solution Q31-2 was 0.2:1;
(3) the solution Q31-2 was placed into an 80° C. oven and dried for 12 h, to obtain a powder G31;
(4) the powder G31 was calcined at 500° C. for 1 h to obtain a powder T31; and
(5) the powder T31 was added to a certain volume of water, stirred at room temperature for 1 h, and then centrifuged at 2,500 rmp to obtain a precipitate H31, where the mass ratio of powder T31 to water is 1:2;
(6) the precipitate H31 was placed into an 80° C. oven and dried for 12 h, to obtain a powder G31-2;
(7) the powder G31-2 and SrCl₂ in certain mass were added to water, the SrCl₂ was added according to a proportion of obtaining a solute having a nominal composition of CsCl·PbCl₂·0.18SrCl₂ available, and stirred at 80° C. for 2 h to obtain a solution R31;
(8) the solution R31 was filtered by a filter paper to obtain a powder G31-3 on the filter paper;
(9) the powder G31-3 was calcined at 500° C. for 1 h to obtain a powder T31-2;
(10) the powder T31-2 was added to a certain volume of water, stirred at room temperature for 1 h, and then centrifuged at 2,500 rmp to obtain a precipitate H31-2, where the mass ratio of powder T31-2 to water is 1:2; and
(11) the precipitate H31-2 was subjected to natural drying for 12 h to obtain a material.

The material obtained in Comparative Example 31 was measured by a fluorescence spectrophotometer; under the excitation of a 365 nm blue ray, the material has a low luminescent intensity, the material obtained in Comparative Example 31 was heated up to 125° C. and its luminescent intensity was then measured, and the material was then found to have only 25% of the measured value at room temperature; 1 g of the material obtained in Comparative Example 31 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 31 had very poor stability. After the material obtained in Comparative Example 31 was radiated by a blue ray having a power density of 150 mW/cm² and a wavelength of 365 nm for 24 h, its luminescent intensity declined in a proportion of greater than 81% of its initial value. Test data of Comparative Example 31 is shown in Table 1.

### Comparative Example 32

A method for preparing a luminescent material provided in this comparative example includes the following specific steps:
(1) a chloroform solution Q32 dissolved with CsCl·PbCl₂ was prepared, and the CsCl·PbCl₂ had a mass concentration of 50 g/L;
(2) SBA molecular sieve in certain mass was added to the solution Q32 and stirred at 80° C. for 2 h to obtain a solution Q32-2, where the mass ratio of the SBA molecular sieve to the solution Q32 was 0.2:1;
(3) the solution Q32-2 was placed into an 80° C. oven and dried for 12 h, to obtain a powder G32;
(4) the powder G32 was calcined at 500° C. for 1 h to obtain a powder T32; and
(5) the powder T32 was added to a certain volume of water, stirred at room temperature for 1 h, and then centrifuged at 2,500 rmp to obtain a precipitate H32, where the mass ratio of powder T32 to water is 1:2;
(6) the precipitate H32 was placed into an 80° C. oven and dried for 12 h, to obtain a powder G32-2;
(7) the powder G32-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R32;
(8) the solution R32 was filtered by a filter paper to obtain a powder G32-3 on the filter paper,
(9) the powder G32-3 was calcined at 500° C. for 1 h to obtain a powder T32-2;
(10) the powder T32-2 was added to a certain volume of water, stirred at room temperature for 1 h, and then centrifuged at 2,500 rmp to obtain a precipitate H32-2, where the mass ratio of powder T32-2 to water is 1:2; and
(11) the precipitate H32-2 was placed into an 80° C. oven and dried for 12 h, to obtain a material.

The material obtained in Comparative Example 32 was measured by a fluorescence spectrophotometer; under the excitation of a 365 nm blue ray, the material has a low luminescent intensity; the material obtained in Comparative Example 32 was heated up to 125° C. and its luminescent intensity was then measured, and the material was then found to have only 23% of the measured value at room temperature; 1 g of the material obtained in Comparative Example 32 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 32 had very poor stability. After the material obtained in Comparative Example 32 was radiated by a blue ray having a power density of 150 mW/cm² and a wavelength of 365 nm for 24 h, its luminescent intensity declined in a proportion of greater than 89% of its initial value. Test data of Comparative Example 32 is shown in Table 1.

### Comparative Example 33

A method for preparing a luminescent material provided in this comparative example includes the following specific steps:
(1) a chloroform solution Q33 dissolved with CsCl·PbCl₂ was prepared, and the CsCl·PbCl₂ had a mass concentration of 50 g/L;
(2) SBA molecular sieve in certain mass was added to the solution Q33 and stirred at 80° C. for 2 h to obtain a solution Q33-2, where the mass ratio of the SBA molecular sieve to the solution Q33-2 was 0.2:1;
(3) the solution Q33-2 was placed into an 80° C. oven and dried for 12 h, to obtain a powder G33;
(4) the powder G33 was calcined at 500° C. for 1 h to obtain a powder T33; and
(5) the powder T33 was added to a certain volume of water, stirred at room temperature for 1 h, and then centrifuged at 2,500 rmp to obtain a precipitate H33, where the mass ratio of powder T33 to water is 1:2;
(6) the precipitate H33 was placed into an 80° C. oven and dried for 12 h, to obtain a powder G33-2;
(7) the powder G33-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R33;
(8) the solution R33 was filtered by a filter paper to obtain a powder G33-3 on the filter paper; and
(9) the powder G33-3 was calcined at 500° C. for 1 h to obtain a material.

The material obtained in Comparative Example 33 was measured by a fluorescence spectrophotometer; under the excitation of a 365 nm blue ray, the material has a low luminescent intensity; the material obtained in Comparative Example 33 was heated up to 125° C. and its luminescent intensity was then measured, and the material was then found to have only 22% of the measured value at room temperature; 1 g of the material obtained in Comparative Example 33 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 33 had very poor stability. After the material obtained in Comparative Example 33 was radiated by a blue ray having a power density of 150 mW/cm² and a wavelength of 365 nm for 24 h, its luminescent intensity declined in a proportion of greater than 88% of its initial value. Test data of Comparative Example 33 is shown in Table 1.

### Comparative Example 34

A method for preparing a luminescent material provided in this comparative example includes the following specific steps:
(1) a chloroform solution Q34 dissolved with CsCl·PbCl₂ was prepared, and the CsCl·PbCl₂ had a mass concentration of 50 g/L;
(2) SBA molecular sieve in certain mass was added to the solution Q34 and stirred at 80° C. for 2 h to obtain a solution Q34-2, where the mass ratio of the SBA molecular sieve to the solution Q34-2 was 0.2:1;
(3) the solution Q34-2 was placed into an 80° C. oven and dried for 12 h, to obtain a powder G34;
(4) the powder G34 was calcined at 500° C. for 1 h to obtain a powder T34; and
(5) the powder T34 was added to a certain volume of water, stirred at room temperature for 1 h, and then centrifuged at 2,500 rmp to obtain a precipitate H34, where the mass ratio of powder T34 to water is 1:2;
(6) the precipitate H34 was placed into an 80° C. oven and dried for 12 h, to obtain a powder G34-2;
(7) the powder G34-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R34;
(8) the solution R34 was filtered by a filter paper to obtain a powder on the filter paper; a material was obtained after the powder was natural drying.

The material obtained in Comparative Example 34 was measured by a fluorescence spectrophotometer; under the excitation of a 365 nm blue ray, the material has a low luminescent intensity; the material obtained in Comparative Example 34 was heated up to 125° C. and its luminescent intensity was then measured, and the material was then found to have only 11% of the measured value at room temperature; 1 g of the material obtained in Comparative Example 34 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 34 had very poor stability. After the material obtained in Comparative Example 34 was radiated by a blue ray having a power density of 150 mW/cm² and a wavelength of 365 nm for 24 h, its luminescent intensity declined in a proportion of greater than 75% of its initial value. Test data of Comparative Example 34 is shown in Table 1.

### Comparative Example 35

A method for preparing a luminescent material provided in this comparative example includes the following specific steps:
(1) a chloroform solution Q35 dissolved with CsCl·PbCl₂ was prepared, and the CsCl·PbCl₂ had a mass concentration of 50 g/L;
(2) SBA molecular sieve in certain mass was added to the solution Q35 and stirred at 80° C. for 2 h to obtain a solution Q35-2, where the mass ratio of the SBA molecular sieve to the solution Q35 was 0.2:1;
(3) the solution Q35-2 was placed into an 80° C. oven and dried for 12 h, to obtain a powder G35;
(4) the powder G35 was calcined at 500° C. for 1 h to obtain a powder T35;
(5) the powder T35 was added to a certain volume of water, stirred at room temperature for 1 h, and then centrifuged at 2,500 rmp to obtain a precipitate H35, where the mass ratio of powder T35 to water is 1:2;
(6) the precipitate H35 was placed into an 80° C. oven and dried for 12 h, to obtain a powder G35-2;
(7) the powder G35-2 and SrCl₂ in certain mass were added to water; the SrCl₂ was added according to a proportion of obtaining a solute having a nominal composition of CsCl·PbCl₂·0.18SrCl₂ available, and stirred at 80° C. for 2 h to obtain a solution R35;
(8) the solution R35 was filtered by a filter paper to obtain a powder G35-2 on the filter paper; and
(9) the powder H35-2 was placed into an 80° C. oven and dried for 12 h, to obtain a material.

The material obtained in Comparative Example 35 was measured by a fluorescence spectrophotometer; under the excitation of a 365 nm blue ray, the material has a low luminescent intensity; the material obtained in Comparative Example 35 was heated up to 125° C. and its luminescent intensity was then measured, and the material was then found to have only 21% of the measured value at room temperature; 1 g of the material obtained in Comparative Example 35 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 35 had very poor stability. After the material obtained in Comparative Example 35 was radiated by a blue ray having a power density of 150 mW/cm² and a wavelength of 365 nm for 24 h, its luminescent intensity declined in a proportion of greater than 79% of its initial value. Test data of Comparative Example 35 is shown in Table 1.

### Comparative Example 36

A method for preparing a luminescent material provided in this comparative example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q36 with a mass concentration of 50 g/L and a solute having a nominal composition of CsCl·0.8PbCl₂·0.18SrCl₂.
(2) the solution Q36 obtained in the step (1) was evaporated at 80° C. until the solvent water was volatilized completely to obtain a powder G36;
(3) the powder G36 was calcined at 500° C. for 1 h to obtain a powder T36;
(4) the powder G36 was added to a certain volume of ethyl orthosilicate, where the mass ratio of powder T36 to ethyl orthosilicate was 1:2, stirred at room temperature for 1 h, and a proper amount of acetic acid was added, then a pH value of the solution was adjusted, after ethyl orthosilicate was hydrolyzed fully, the solution was centrifuged at 2,500 rmp to obtain a precipitate H36; and
(5) the precipitate H36 was calcined at 500° C. for 1 h to obtain a material.

The material obtained in Comparative Example 36 was measured by a fluorescence spectrophotometer; under the excitation of a 365 nm blue ray, the material has a low luminescent intensity; the material obtained in Comparative Example 36 was heated up to 125° C. and its luminescent intensity was then measured, and the material was then found to have only 26% of the measured value at room temperature; 1 g of the material obtained in Comparative Example 36 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be extremely low. Obviously, the material obtained in Comparative Example 36 had very poor stability. After the material obtained in Comparative Example 36 was radiated by a blue ray having a power density of 150 mW/cm² and a wavelength of 365 nm for 24 h, its luminescent intensity declined in a proportion of greater than 78% of its initial value. Test data of Comparative Example 36 is shown in Table 1.

### Example 1

A method for preparing a luminescent material provided in this example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q37 with a mass concentration of 50 g/L and containing a solute having a nominal composition of CsCl·0.8PbCl₂·0.18SrCl₂.
(2) SBA molecular sieve in certain mass was added to the solution Q37 obtained in the step (1) and stirred at 80° C. for 2 h to obtain a solution R37, where the mass ratio of the SBA molecular sieve to the solution Q37 was 0.2:1;
(3) the solution R37 obtained in the step (2) was evaporated at 80° C. until the solvent water was volatilized completely to obtain a powder G37;
(4) the powder G37 was calcined at 500° C. for 1 h to obtain a powder T37;
(5) the powder T37 was added to a certain volume of water, stirred at room temperature for 1 h, and then centrifuged at 2,500 rmp to obtain a precipitate H37, where the mass ratio of powder T37 to water is 1:2; and
(6) the precipitate H37 was placed into an 80° C. oven and dried for 12 h, to obtain a material.

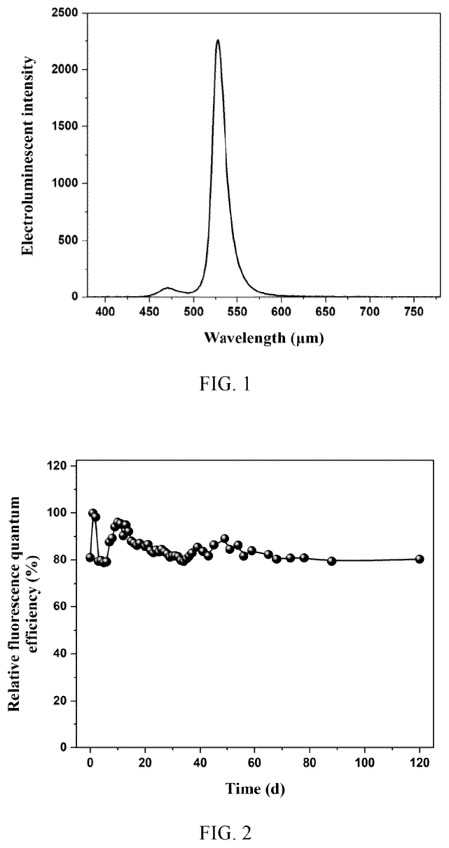

The material obtained in Example 1 was measured by a fluorescence spectrophotometer; under the excitation of a 365 nm blue ray, the material had a very high luminescent intensity with an emission spectrum as shown in FIG. 1; the material obtained in Example 1 was heated up to 125° C., and its luminescent intensity was then measured and declined in a proportion of not greater than 45% at room temperature; 1 g of the material obtained in Example 1 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be basically the same. Moreover, after the material obtained in Example 1 was radiated by a blue ray having a power density of 150 mW/cm² and a wavelength of 365 inn for 24 h, its luminescent intensity was found to be basically the same. Test data of Example 1 is shown in Table 1.

### Example 2

A method for preparing a luminescent material provided in this example includes the following specific steps:
(1) CsCl, PbCl₂, and SrCl₂ were heated at 80° C. in a proportion of CsCl·0.75PbCl₂·0.05SrCl₂ as its nominal composition and completely dissolved into a solvent water, to obtain a solution Q38 with a mass concentration of 50 g/L and containing a solute having a nominal composition of CsCl·0.75PbCl₂·0.05SrCl₂.
(2) SBA molecular sieve in certain mass was added to the solution Q38 obtained in the step (1) and stirred at 80° C. for 2 h to obtain a solution R38, where the mass ratio of the SBA molecular sieve to the solution Q38 was 0.2:1;
(3) the solution R38 obtained in the step (2) was evaporated at 80° C. until the solvent water was volatilized completely to obtain a powder G38;
(4) the powder G38 was calcined at 500° C. for 1 h to obtain a powder T38;
(5) the powder T38 was added to a certain volume of water, stirred at room temperature for 1 h, and then centrifuged at 2,500 rmp to obtain a precipitate H38, where the mass ratio of powder T38 to water is 1:2; and
(6) the precipitate H38 was placed into an 80° C. oven and dried for 12 h, to obtain a material.

The material obtained in Example 2 was measured by a fluorescence spectrophotometer; under the excitation of a 365 nm blue ray, the material had a very high luminescent intensity; the material obtained in Example 2 was heated up to 125° C.; its luminescent intensity was then measured and declined in a proportion of not greater than 46% at room temperature; 1 g of the material obtained in Example 2 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be basically the same. Moreover, after the material obtained in Example 2 was radiated by a blue ray having a power density of 150 mW/cm² and a wavelength of 365 nm for 24 h, its luminescent intensity was found to be basically the same. Test data of Example 2 is shown in Table 1.

### Example 3

A method for preparing a luminescent material provided in this example includes the following specific steps:
(1) CsCl, PbCl₂, and SrCl₂ were heated at 80° C. in a proportion of CsCl·0.95PbCl₂·0.04SrCl₂ as its nominal composition and completely dissolved into a solvent water, to obtain a solution Q39 with a mass concentration of 50 g/L and containing a solute having a nominal composition of CsCl·0.95PbCl₂·0.04SrCl₂.
(2) SBA molecular sieve in certain mass was added to the solution Q39 obtained in the step (1) and stirred at 80° C. for 2 h to obtain a solution R39, where the mass ratio of the SBA molecular sieve to the solution Q39 was 0.2:1;
(3) the solution R39 obtained in the step (2) was evaporated at 80° C. until the solvent water was volatilized completely to obtain a powder G39;
(4) the powder G39 was calcined at 500° C. for 1 h to obtain a powder T39;
(5) the powder T39 was added to a certain volume of water, stirred at room temperature for 1 h, and then centrifuged at 2,500 rmp to obtain a precipitate H39, where the mass ratio of powder T39 to water is 1:2; and
(6) the precipitate H39 was placed into an 80° C. oven and dried for 12 h, to obtain a material.

The material obtained in Example 3 was measured by a fluorescence spectrophotometer; under the excitation of a 365 nm blue ray, the material had a very high luminescent intensity; the material obtained in Example 3 was heated up to 125° C.; its luminescent intensity was then measured and declined in a proportion of not greater than 42% at room temperature; 1 g of the material obtained in Example 3 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be basically the same. Moreover, after the material obtained in Example 3 was radiated by a blue ray having a power density of 150 mW/cm² and a wavelength of 365 nm for 24 h, its luminescent intensity was found to be basically the same. Test data of Example 3 is shown in Table 1.

### Example 4

A method for preparing a luminescent material provided in this example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q40 with a mass concentration of 50 g/L and containing a solute having a nominal composition of CsCl·0.8PbCl₂·0.18SrCl₂.
(2) SBA molecular sieve in certain mass was added to the solution Q40 obtained in the step (1) and stirred at 80° C. for 2 h to obtain a solution R40, where the mass ratio of the SBA molecular sieve to the solution Q40 was 0.2:1;
(3) the solution R40 obtained in the step (2) was evaporated at 80° C. until the solvent water was volatilized completely to obtain a powder G40;
(4) the powder G40 was calcined at 500° C. for 1 h to obtain a powder T40;
(5) the powder T40 was added to a certain volume of water, stirred at room temperature for 1 h, and then centrifuged at 2,500 rmp to obtain a precipitate H40, where the mass ratio of powder T40 to water is 1:2; and
(6) the precipitate H40 was placed into an 80° C. oven and dried for 12 h, to obtain a material.

The material obtained in Example 4 was measured by a fluorescence spectrophotometer; under the excitation of a 365 nm blue ray, the material had a very high luminescent intensity; the material obtained in Example 4 was heated up to 125° C.; its luminescent intensity was then measured and declined in a proportion of not greater than 49% at room temperature; 1 g of the material obtained in Example 4 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be basically the same. Moreover, after the material obtained in Example 4 was radiated by a blue ray having a power density of 150 mW/cm² and a wavelength of 365 nm for 24 h, its luminescent intensity was found to be basically the same. Test data of Example 4 is shown in Table 1.

### Example 5

A method for preparing a luminescent material provided in this example includes the following specific steps:
(1) CsCl, PbCl₂, and SrCl₂ were heated at 80° C. in a proportion of CsCl·0.8PbCl₂·0.18SrCl₂ as its nominal composition and completely dissolved into a solvent water, to obtain a solution Q41 with a mass concentration of 50 g/L and containing a solute having a nominal composition of CsCl·0.8PbCl₂·0.18SrCl₂.
(2) 5A molecular sieve in certain mass was added to the solution Q41 obtained in the step (1) and stirred at 80° C. for 2 h to obtain a solution R41, where the mass ratio of the SBA molecular sieve to the solution Q41 was 0.2:1;
(3) the solution R41 obtained in the step (2) was evaporated at 80° C. until the solvent water was volatilized completely to obtain a powder G41;
(4) the powder G41 was calcined at 500° C. for 1 h to obtain a powder T41;
(5) the powder T41 was added to a certain volume of water, stirred at room temperature for 1 h, and then centrifuged at 2,500 rmp to obtain a precipitate H41, where the mass ratio of powder T41 to water is 1:2; and
(6) the precipitate H41 was placed into an 80° C. oven and dried for 12 h, to obtain a material.

The material obtained in Example 5 was measured by a fluorescence spectrophotometer; under the excitation of a 365 nm blue ray, the material had a very high luminescent intensity; the material obtained in Example 5 was heated up to 125° C.; its luminescent intensity was then measured and declined in a proportion of not greater than 48% at room temperature; 1 g of the material obtained in Example 5 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be basically the same. Moreover, after the material obtained in Example 5 was radiated by a blue ray having a power density of 150 mW/cm² and a wavelength of 365 nm for 24 h, its luminescent intensity was found to be basically the same. Test data of Example 5 is shown in Table 1.

### Example 6

A method for preparing a luminescent material provided in this example includes the following specific steps:
(1) CsCl, PbCl₂, and SrCl₂ were heated at 80° C. in a proportion of CsCl·0.8PbCl₂·0.21SrCl₂ as its nominal composition and completely dissolved into a solvent water, to obtain a solution Q42 with a mass concentration of 50 g/L and containing a solute having a nominal composition of CsCl·0.8PbCl₂·0.21SrCl₂.
(2) 5A molecular sieve in certain mass was added to the solution Q42 obtained in the step (1) and stirred at 80° C. for 2 h to obtain a solution R42, where the mass ratio of the SBA molecular sieve to the solution Q42 was 0.2:1;
(3) the solution R42 obtained in the step (2) was evaporated at 80° C. until the solvent water was volatilized completely to obtain a powder G42;
(4) the powder G42 was calcined at 500° C. for 1 h to obtain a powder T42;
(5) the powder T42 was added to a certain volume of water, stirred at room temperature for 1 h, and then centrifuged at 2,500 rmp to obtain a precipitate H42, where the mass ratio of powder T42 to water is 1:2; and
(6) the precipitate H42 was placed into an 80° C. oven and dried for 12 h, to obtain a material.

The material obtained in Example 6 was measured by a fluorescence spectrophotometer; under the excitation of a 365 nm blue ray, the material had a high luminescent intensity; the material obtained in Example 6 was heated up to 125° C.; its luminescent intensity was then measured and declined in a proportion of not greater than 48% at room temperature; 1 g of the material obtained in Example 6 was taken and added to 100 g of water to detect the material stability, subjected to standing for 24 h and filtered with a filter paper; the substance on the filter paper was dried for 24 h at 80° C., and the dried material on the filter paper was measured by the fluorescence spectrophotometer, and the luminescent intensity was found to be basically the same. Moreover, after the material obtained in Example 6 was radiated by a blue ray having a power density of 150 mW/cm² and a wavelength of 365 nm for 24 h, its luminescent intensity was found to be basically the same. Test data of Example 6 is shown in Table 1.

### Example 7

The material obtained in Example 1 was put to water. The sample was taken out every other a period of time, and dried in an 80° C. oven for 12 h, to obtain a material. The corresponding material in Example 7 was measured by a quantum efficiency tester; under the excitation of a 365 nm blue ray, the variation curve of the quantum efficiency of the luminescent material over time is shown in FIG. 2. As can be seen, the corresponding luminescent material in Example 7 has a very high stability to water.

TABLE I
Table for test results of the material property

| | | Luminescent | Luminescent | |
|---|---|---|---|---|
| | | intensity | intensity | Luminescent |
| | | (Thermal | (Test for | intensity |
| | Luminescent | quenching | water | (Light |
| No. | intensity | property) | resistance) | stability) |
| Comparative | 32.1 | 5.5 | 0.2 | 7.6 |
| Example 1 | | | | |
| Comparative | / | / | / | / |
| Example 2 | | | | |
| Comparative | / | / | / | / |
| Example 3 | | | | |
| Comparative | / | / | / | / |
| Example 4 | | | | |
| Comparative | / | / | / | / |
| Example 5 | | | | |
| Comparative | / | / | / | / |
| Example 6 | | | | |
| Comparative | / | / | / | / |
| Example 7 | | | | |
| Comparative | 1.5 | / | | / |
| Example 8 | | | | |
| Comparative | / | / | / | / |
| Example 9 | | | | |
| Comparative | 5.2 | 0.52 | / | 0.5 |
| Example 10 | | | | |
| Comparative | 53 | 10.6 | 2.3 | 10.6 |
| Example 11 | | | | |
| Comparative | 16.3 | 3.5 | 2.1 | 4.1 |
| Example 12 | | | | |
| Comparative | 15.1 | 3.6 | 1.8 | 2.7 |
| Example 13 | | | | |
| Comparative | 10.2 | 2.3 | 0.3 | 2.3 |
| Example 14 | | | | |
| Comparative | 121 | 25.4 | 1.3 | 37.5 |
| Example 15 | | | | |
| Comparative | 18.7 | 4.4 | 1.5 | 6.5 |
| Example 16 | | | | |
| Comparative | 18.5 | 4.2 | 2.1 | 5.7 |
| Example 17 | | | | |
| Comparative | 19.9 | 4.3 | 2.7 | 6.1 |
| Example 18 | | | | |
| Comparative | 2.3 | / | / | / |
| Example 19 | | | | |
| Comparative | 10.8 | 2.9 | 2.4 | 2.9 |
| Example 20 | | | | |
| Comparative | 16.1 | 3.3 | 2.6 | 4.6 |
| Example 21 | | | | |
| Comparative | 19.2 | 4.2 | 2.1 | 4.2 |
| Example 22 | | | | |
| Comparative | 23.3 | 5.5 | 1.9 | 7.9 |
| Example 23 | | | | |
| Comparative | 24.7 | 6.1 | 1.8 | 7.6 |
| Example 24 | | | | |
| Comparative | 25.1 | 6.2 | 2.1 | 7.1 |
| Example 25 | | | | |
| Comparative | 24.8 | 5.4 | 2.6 | 6.6 |
| Example 26 | | | | |
| Comparative | 29.3 | 3.2 | 2.9 | 7.3 |
| Example 27 | | | | |
| Comparative | 32.1 | 6.7 | 3.1 | 8.3 |
| Example 28 | | | | |
| Comparative | 33.5 | 7.3 | 3.5 | 7.7 |
| Example 29 | | | | |
| Comparative | 34.2 | 8.2 | 3.2 | 9.5 |
| Example 30 | | | | |
| Comparative | 31.3 | 7.8 | 2.6 | 5.9 |
| Example 31 | | | | |
| Comparative | 27.6 | 6.3 | 3.4 | 3.1 |
| Example 32 | | | | |
| Comparative | 22.1 | 4.8 | 3.3 | 2.6 |
| Example 33 | | | | |
| Comparative | 28.2 | 3.1 | 2.9 | 7.1 |
| Example 34 | | | | |
| Comparative | 26.1 | 5.4 | 2.7 | 5.4 |
| Example 35 | | | | |
| Comparative | 23.2 | 6.1 | 2.6 | 5.1 |
| Example 36 | | | | |
| Example 1 | 2230 | 1003 | 2225 | 2215 |
| Example 2 | 2751 | 1265 | 2745 | 2705 |
| Example 3 | 3022 | 1269 | 3020 | 3018 |
| Example 4 | 1520 | 744 | 1515 | 1501 |
| Example 5 | 1950 | 936 | 1948 | 1948 |
| Example 6 | 263 | 126 | 251 | 233 |

What is described above are preferred embodiments of the present invention. However, the present invention is not limited to the concrete details in the above embodiments. The technical solutions of the present invention can be transformed simply and variously within the technical conception of the present invention. Moreover, these simple deformations fall within the protection scope of the present invention.

In addition, it needs to be indicated that each specific technical feature in the above detailed embodiments can be combined with each other in any proper way in the absence of contradiction. To avoid unnecessary repetition, each possible way of combination will be not specified separately in the present invention.

Furthermore, different embodiments of the present invention can be combined at will as long as it falls within the idea of the present invention; and these combinations shall be deemed to be within the disclosure of the present invention.

1. A luminescent material, wherein the luminescent material is formed by compounding a porous material with a luminescent substance, and has a chemical formula of: N@AX·aPbX₂·bMX₂; wherein N denotes the porous material, @ denotes compounding, and AX·aPbX₂·bMX₂ denotes the luminescent substance, and wherein A is at least one of Cs and Rb, X is at least one of Cl, Br, and I; M is at least one of Mg, Ca, Sr, Ba, Zn, and Cu, and 0.7<a≤1, 0<b≤0.3, and 0.7<a+b<1.

2. The luminescent material according to claim 1, wherein the N is at least one of mesoporous silica, a KIT-6 molecular sieve, an MCM-41 molecular sieve, an SBA molecular sieve, an MCM-22 molecular sieve, a titanium silicon molecular sieve TS-1, an SAPO-34 molecular sieve, an SAPO-11 molecular sieve, a ZSM-5 molecular sieve, a Y-type molecular sieve, a ZSM-35 molecular sieve, a β molecular sieve, a ZSM-23 molecular sieve, a 3A molecular sieve, 4A molecular sieve, A 5A molecular sieve, and a 13X molecular sieve;
optionally, chemical bonding is present between the porous material and the luminescent substance, i.e., a dangling bond on a surface of the AX·aPbX₂·bMX₂ contacts with a solvent to form a passivation layer subjected to chemical bonding with a dangling bond on an inside wall of a pore of the N, to form a stable chemical bond; and
optionally, during preparation of the luminescent substance, a solution having a nominal composition of AX·aPbX₂·bMX₂ is passivated with a solvent and then compounded with the porous material, calcined at a temperature of 450-900° C., washed and dried to obtain the luminescent material.

3. The luminescent material according to claim 1 or 2, wherein the luminescent material is excited by any light having a wavelength range of 300-365 nm to obtain a spectrum having a wavelength of 460-760 and a full width at half maximum (FWHM) of 15-30 nm;
optionally, a luminescent intensity of the luminescent material after being soaked into water for 200 d declines in a proportion of not greater than 10% of an initial value thereof;
optionally, a luminescent intensity of the luminescent material at 125° C. declines in a proportion of not greater than 50% of a luminescent intensity thereof at room temperature; and
optionally, a luminescent intensity of the luminescent material after being irradiated by a blue ray having a power density of 150 mW/cm² and a wavelength of 365 nm for 2,000 h declines in a proportion of not greater than 40% of an initial value thereof.

4. A method for preparing the luminescent material according to any one of claims 1-3, comprising the following steps:
(1) preparing each material according to the chemical formula, mixing an A-containing compound, a Pb-containing compound and an M-containing compound in a proportion of AX·aPbX₂·bMX₂ as a nominal composition, and adding a solvent S such that a solute is dissolved into the solvent S, to obtain a solution Q with a solute having a nominal composition of AX·aPbX₂·bMX₂;
(2) adding a porous material N to the solution Q obtained in the step (1), heating and stirring evenly to obtain a solution R;
(3) evaporating the solution R obtained in the step (2) until the solvent S is volatilized completely to obtain a powder G;
(4) calcining the powder G to obtain a powder T;
(5) adding the powder T to water, performing stirring and centrifugation to obtain a precipitate H; and
(6) drying the precipitate H to obtain the luminescent material.

5. The method for preparing the luminescent material according to claim 4, wherein in the step (1), the A-containing compound is at least one of CsX and RbX, and X is at least one of Cl, Br, and I; the Pb-containing compound is PbX₂, and X is at least one of Cl, Br, and I; the M-containing compound is a halide containing Mg, Ca, Sr, Ba, Zn, and Cu, and the solvent S is water or a haloid acid; alternatively, the M-containing compound is at least one of nitrates containing Mg, Ca, Sr, Ba, Zn, and Cu, and the solvent S is a haloid acid;
optionally, the A-containing compound, the Pb-containing compound and the M-containing compound are mixed in a proportion of AX·aPbX₂·bMX₂ as a nominal composition, heated at 50-90° C. until these compounds are completely dissolved into the solvent S, and the solution Q with a solute having a nominal composition of AX·aPbX₂·bMX₂ has a mass concentration of 5 g/L-100 g/L.

6. The method for preparing the luminescent material according to claim 4, wherein in the step (2), a mass ratio of the porous material N to the solution Q is 0.1:1-0.5:1, and the solution R is obtained at a heating temperature of 50-90° C. and a stirring time of 1-3 h; and
optionally, in the step (3), an evaporation temperature is 75-85° C.

7. The method for preparing the luminescent material according to any one of claims 4-6, wherein in the step (4), the calcining is performed at a temperature of 450-900° C. for 0.5-6 h; and
optionally, in the step (5) of adding the powder T to water, a mass ratio of the water to the powder T is 1:1-1:5; the centrifugation is performed at a rate of 500-3000 rmp, and the precipitate H is obtained after the centrifugation.

8. Use of the luminescent material according to any one of claims 1-3, or a luminescent material prepared by the method for preparing the luminescent material according to any one of claims 4-7 in white-light illumination and/or a backlight source for display.

9. A light-emitting diode (LED) device, comprising the luminescent material according to any one of claims 1-3, or a luminescent material prepared by the method for preparing the luminescent material according to any one of claims 4-7.

10. The LED device according to claim 9, wherein the LED device is a Mini-LED device comprising an LED chip with a size of (0.05 mm-0.2 mm)×(0.05 mm-0.2 mm) and a luminescent layer, wherein the LED chip emits a spectrum having a wavelength range of 300-470 nm; the luminescent layer is a silica gel layer solidified with the luminescent material or an epoxy resin layer solidified with the luminescent material; the luminescent material accounts for 5-75% of a total mass of the luminescent layer by mass.
